(19) United States
(12) Patent Application Publication
(10) Pub. No.: US 2026/0013347 A1
(43) Pub. Date: Jan. 8, 2026

(54) DISPLAY SUBSTRATE AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Changlong YUAN, Beijing (CN); Xiaoxiao WANG, Beijing (CN); Li ZHU, Beijing (CN); Jingyi FENG, Beijing (CN)

(21) Appl. No.: 18/992,199

(22) PCT Filed: May 24, 2024
(86) PCT No.: PCT/CN2024/095268

§ 371 Date: Jan. 8, 2025

(30) Foreign Application Priority Data
May 26, 2023 (CN) 202310612797.X

(51) Int. Cl. H10K 59/131; H10K 59/121

(52) U.S. Cl. CPC H10K 59/131; H10K 59/121

(57) ABSTRACT

A display substrate includes a based substrate, pixel drive circuits in a plurality of rows and columns, light emitting devices in a plurality of rows and columns, a plurality of data signal lines and a plurality of anode connection lines, which are disposed on the based substrate; the based substrate includes a first drive region in which the pixel drive circuits and the data signal lines are located, and the light emitting devices and the anode connection lines are located at least partially; the light emitting device includes a first light emitting device, a second light emitting device and a third light emitting device, a plurality of first light emitting devices and a plurality of second light emitting devices are alternately arranged in a column direction, and a plurality of third light emitting devices are arranged in the column direction.

### CROSS-REFERENCE TO RELATED APPLICATIONS

This application is a national stage application of PCT Application No. PCT/CN2024/095268, which is filed on May 24, 2024 and claims priority of Chinese Patent Application No. 202310612797.X, filed on May 26, 2023 and entitled “Display Substrate and Display Apparatus”, the content of which should be regarded as being incorporated herein by reference.

### TECHNICAL FIELD

The present disclosure relates to, but is not limited to, the field of display technologies, and more particularly, to a display substrate and a display apparatus.

### BACKGROUND

An Organic Light Emitting Diode (OLED) and a Quantum dot Light Emitting Diode (QLED) are active light emitting display devices and have advantages of self-illumination, a wide viewing angle, a high contrast ratio, low power consumption, an extremely high reaction speed, lightness and thinness, flexibility, and a low cost, etc. With constant development of display technologies, a flexible display apparatus (Flexible Display) in which an OLED or a QLED is used as a light emitting device and signal control is performed through a Thin Film Transistor (TFT for short) has become a mainstream product in the field of display at present.

### SUMMARY

The following is a summary of subject matter described in the present disclosure in detail. This summary is not intended to limit the protection scope of claims.

In a first aspect, the present disclosure provides a display substrate, including a based substrate, pixel drive circuits in a plurality of rows and columns, light emitting devices in a plurality of rows and columns, a plurality of data signal lines and a plurality of anode connection lines, which are disposed on the base substrate, the base substrate includes a first drive region in which the pixel drive circuits and the data signal lines are located, and the light emitting devices and the anode connection lines are located, at least partially; a pixel drive circuit is connected to a data signal line and a light emitting device, respectively, the light emitting device includes a first light emitting device, a second light emitting device and a third light emitting device, a plurality of first light emitting devices and a plurality of second light emitting devices are alternately arranged in a column direction, and a plurality of third light emitting devices are arranged in the column direction, a light emitting device includes a first electrode;
in the first drive region, a light emitting device in an n-th row and a (4a−3)-th column is a first light emitting device, a light emitting device in the n-th row and a (4a−1)-th column is a second light emitting device, a light emitting device in an (n+1)-th row and the (4a−3)-th column is a second light emitting device, a light emitting device in the (n+1)-th row and the (4a−1)-th column is a first light emitting device, and a light emitting device in an even-numbered column is a third light emitting device, wherein 1≤a≤M/4, 1≤n≤N−1, M is a total number of columns of light emitting devices or pixel drive circuits in the first drive region, and is an even number, N is a total number of rows of light emitting devices or pixel drive circuits in the first drive region;
a pixel drive circuit in one of the odd-numbered column and the even-numbered column is electrically connected with the first electrode of the first light emitting device or the second light emitting device through the anode connection line, and a pixel drive circuit in the other of the odd-numbered column and the even-numbered column is electrically connected with the first electrode of the third light emitting device;
an orthographic projection of a first electrode of a light emitting device connected to a pixel drive circuit in the n-th row and a (2f−1)-th column on the base substrate is partially overlapped with an orthographic projection of a region where a pixel drive circuit in the n-th row and a (2f+1)-th column is located on the base substrate, an orthographic projection of a first electrode of a light emitting device connected to the pixel drive circuit in the n-th row and the (2f+1)-th column on the base substrate is partially overlapped with an orthographic projection of a region where a pixel drive circuit in the n-th row and a (2f−1)-th column is located on the base substrate, and an orthographic projection of a first electrode of a light emitting device connected to a pixel drive circuit in the n-th row and the even-numbered column on the base substrate is partially overlapped with an orthographic projection of a region where the pixel drive circuit in the n-th row and the even-numbered column is located on the base substrate, wherein 1≤f≤M/2, and f is an odd.

In an exemplary implementation, the pixel drive circuit is provided with an anode connection via through which the first electrode of the light emitting device is electrically connected with the pixel drive circuit, and the pixel drive circuit includes a first pixel drive circuit configured to drive the first light emitting device to emit light, a second pixel drive circuit configured to drive the second light emitting device to emit light, and a third pixel drive circuit configured to drive the third light emitting device to emit light;
a pixel drive circuit in an odd-numbered column is a first pixel drive circuits or a second pixel drive circuit, a pixel drive circuit in an adjacent odd-numbered column is different, and the even-numbered column pixel drive circuit is the third pixel drive circuit;
an orthographic projection of a first electrode of at least one first light emitting device on the base substrate is partially overlapped with an orthographic projection of an anode connection line to which the first light emitting device is connected on the base substrate;
the orthographic projection of the first electrode of the at least one first light emitting device on the base substrate is not overlapped with an orthographic projection of an anode connection via of the first pixel drive circuit to which the first light emitting device is connected on the base substrate;
an orthographic projection of a first electrode of at least one second light emitting device on the base substrate is partially overlapped with an orthographic projection of an anode connection line to which the second light emitting device is connected on the base substrate;
the orthographic projection of the first electrode of the at least one second light emitting device on the base substrate is not overlapped with an orthographic projection of an anode connection via of the second pixel drive circuit to which the second light emitting device is connected on the base substrate;
an orthographic projection of a first electrode of the third light emitting device on the base substrate is partially overlapped with an orthographic projection of an anode connection via of the third pixel drive circuit to which the third light emitting device is connected on the base substrate.

In an exemplary implementation, the anode connection line includes a first anode connection line and a second anode connection line;
the first anode connection line is electrically connected with a part of the first pixel drive circuits, and with a first electrode of a first light emitting device to which the part of the first pixel drive circuits is connected, respectively; an orthographic projection of the first anode connection line on the base substrate is partially overlapped with an orthographic projection of an anode connection via of the connected first pixel drive circuit on the base substrate, and is partially overlapped with an orthographic projection of the first electrode of the connected first light emitting device on the base substrate;
the second anode connection line is electrically connected with a part of the second pixel drive circuits, and with a first electrode of a second light emitting device to which the part of the second pixel drive circuits is connected, respectively; an orthographic projection of the second anode connection line on the base substrate is partially overlapped with an orthographic projection of an anode connection via of the connected second pixel drive circuit on the base substrate, and is partially overlapped with an orthographic projection of the first electrode of the connected second light emitting device on the base substrate.

In an exemplary implementation, the orthographic projection of the first anode connection line on the base substrate is at least partially overlapped with the orthographic projection of the second anode connection line on the base substrate.

In an exemplary implementation, the first anode connection line and the second anode connection line are linear, an extending direction of the first anode connection line intersects with an extending direction of the second anode connection line, and both the extending direction of the first anode connection line and the extending direction of the second anode connection line are different from a row direction and a column direction;
the orthographic projection of the first anode connection line on the base substrate is not overlapped with the orthographic projections of the first electrode of the second light emitting device and the first electrode of the third light emitting device on the base substrate, the orthographic projection of the second anode connection line on the base substrate is not overlap with the orthographic projections of the first electrode of the first light emitting device and the first electrode of the third light emitting device on the base substrate, and the first anode connection line and the second anode connection line are located on a same side of the anode connection via of the third pixel drive circuit.

In an exemplary implementation, the first anode connection line and the second anode connection line include a first connection segment and a second connection segment, a first connection segment and a second connection segment located in a same anode connection line are connected and disposed at a right angle, the first connection segment extends along a column direction, and the second connection segment extends along a row direction;
an orthographic projection of the first connection segment of the first anode connection line on the base substrate is partially overlapped with the orthographic projections of the anode connection via of the first pixel drive circuit and the first electrode of the second light emitting device on the base substrate, an orthographic projection of the second connection segment of the first anode connection line on the base substrate is partially overlapped with an orthographic projection of the second connection segment of the second anode connection line on the base substrate, and the orthographic projections of the first electrode of the first light emitting device and the first electrode of the second light emitting device on the base substrate; an orthographic projection of the first connection segment of the second anode connection line on the base substrate is partially overlapped with the orthographic projections of the anode connection via of the second pixel drive circuit and the first electrode of the first light emitting device on the base substrate, the orthographic projection of the second connection segment of the second anode connection line on the base substrate is partially overlapped with the orthographic projections of the first electrode of the first light emitting device and the first electrode of the second light emitting device on the base substrate;
the orthographic projections of the first anode connection line and the second anode connection line on the base substrate are not overlapped with the orthographic projection of the first electrode of the third light emitting device on the base substrate, and are located on a same side of the anode connection via of the third pixel drive circuit.

In an exemplary implementation, the first anode connection line includes a first connection segment, a second connection segment and a third connection segment, the first connection segment and the third connection segment extend along a column direction, the second connection segment extends along a row direction, the first connection segment and the third connection segment are located on a same side of the second connection segment and electrically connected with the second connection segment, respectively; the second anode connection line includes a fourth connection segment and a fifth connection segment connected with each other and disposed at a right angle, the fourth connection segment extends along the column direction and the fifth connection segment extends along the row direction;
an orthographic projection of the first connection segment of the first anode connection line on the base substrate is partially overlapped with the orthographic projection of the anode connection via of the first pixel drive circuit on the base substrate, an orthographic projection of the second connection segment of the first anode connection line on the base substrate is partially overlapped with an orthographic projection of the first electrode of the third light emitting device on the base substrate, an orthographic projection of the third connection segment of the first anode connection line on the base substrate is partially overlapped with orthographic projections of the first electrode of the first light emitting device and the fifth connection segment of the second anode connection line on the base substrate, an orthographic projection of the fourth connection segment of the second anode connection line on the base substrate is partially overlapped with the orthographic projections of the anode connection via of the second pixel drive circuit and the first electrode of the first light emitting device on the base substrate, and an orthographic projection of the fifth connection segment of the second anode connection line on the base substrate is partially overlapped with the first electrode of the first light emitting device and the first electrode of the second light emitting device;
the orthographic projection of the second anode connection line on the base substrate is not overlapped with the orthographic projection of the first electrode of the third light emitting device on the base substrate, and the first anode connection line and the second anode connection line are located on different sides of the anode connection via of the third pixel drive circuit.

In an exemplary implementation, the second anode connection line includes a first connection segment, a second connection segment and a third connection segment, the first connection segment and the third connection segment extend along a column direction, the second connection segment extends along a row direction, the first connection segment and the third connection segment are located on a same side of the second connection segment and electrically connected with the second connection segment, respectively; the first anode connection line includes a fourth connection segment and a fifth connection segment connected with each other and disposed at a right angle, the fourth connection segment extends along the column direction and the fifth connection segment extends along the row direction;
an orthographic projection of the fourth connection segment of the first anode connection line on the base substrate is partially overlapped with the orthographic projections of the anode connection via of the first pixel drive circuit and the first electrode of the second light emitting device on the base substrate; an orthographic projection of the fifth connection segment of the first anode connection line on the base substrate is partially overlapped with the orthographic projections of the first electrode of the first light emitting device, the first electrode of the second light emitting device and the third connection segment of the second anode connection line on the base substrate; an orthographic projection of the first connection segment of the second anode connection line on the base substrate is partially overlapped with the orthographic projection of the anode connection via of the second pixel drive circuit on the base substrate; an orthographic projection of the second connection segment of the second anode connection line on the base substrate is partially overlapped with the orthographic projection of the first electrode of the third light emitting device on the base substrate; an orthographic projection of the third connection segment of the second anode connection line on the base substrate is partially overlapped with the orthographic projection of the first electrode of the second light emitting device on the base substrate;
the orthographic projection of the first anode connection line on the base substrate is not overlapped with the orthographic projection of the first electrode of the third light emitting device on the base substrate, and the first anode connection line and the second anode connection line are located on different sides of the anode connection via of the third pixel drive circuit.

In an exemplary implementation, the orthographic projection of the first anode connection line on the base substrate is not overlapped with the orthographic projection of the second anode connection line on the base substrate.

In an exemplary implementation, each of the first anode connection line and the second anode connection line includes a first connection segment, a second connection segment, and a third connection segment, the first connection segment and the third connection segment extend along the column direction, the second connection segment extends along the row direction, the first connection segment and the third connection segment are located on a same side of the second connection segment and electrically connected with the second connection segment, respectively;
an orthographic projection of the first connection segment of the first anode connection line on the base substrate is partially overlapped with the orthographic projection of the anode connection via of the first pixel drive circuit on the base substrate, an orthographic projection of the second connection segment of the first anode connection line on the base substrate is partially overlapped with the orthographic projection of the first electrode of the third light emitting device on the base substrate, an orthographic projection of the third connection segment of the first anode connection line on the base substrate is partially overlapped with the orthographic projection of the first electrode of the first light emitting device on the base substrate, an orthographic projection of the first electrode of the second light emitting device on the base substrate is partially overlapped with the orthographic projection of the anode connection via of the second pixel drive circuit on the base substrate, an orthographic projection of the second connection segment of the second anode connection line on the base substrate is partially overlapped with the orthographic projection of the first electrode of the third light emitting device on the base substrate, an orthographic projection of the third connection segment of the second anode connection line on the base substrate is partially overlapped with the orthographic projection of the first electrode of the second light emitting device on the base substrate,
the first anode connection line and the second anode connection line are located on a same side of the anode connection via of the third pixel drive circuit.

In an exemplary implementation, the first anode connection line includes a first connection segment, a second connection segment and a third connection segment, the first connection segment and the third connection segment extend along a column direction, the second connection segment extends along a row direction, the first connection segment and the third connection segment are located on a same side of the second connection segment and electrically connected with the second connection segment, respectively; the second anode connection line includes a fourth connection segment and a fifth connection segment connected with each other and disposed at an acute angle, the fourth connection segment extends along the column direction;
an orthographic projection of the first connection segment of the first anode connection line on the base substrate is partially overlapped with the orthographic projection of the anode connection via of the first pixel drive circuit on the base substrate, an orthographic projection of the second connection segment of the first anode connection line on the base substrate is partially overlapped, or is not overlapped, with an orthographic projection of the first electrode of the third light emitting device on the base substrate, an orthographic projection of the third connection segment of the first anode connection line on the base substrate is partially overlapped with the orthographic projection of the first electrode of the first light emitting device on the base substrate, an orthographic projection of the fourth connection segment of the second anode connection line on the base substrate is partially overlapped with the orthographic projections of the anode connection via of the second pixel drive circuit and the first electrode of the first light emitting device on the base substrate, and an orthographic projection of the fifth connection segment of the second anode connection line on the base substrate is partially overlapped with the first electrode of the second light emitting device;
the orthographic projection of the second anode connection line on the base substrate is not overlapped with the orthographic projection of the first electrode of the third light emitting device on the base substrate, and the first anode connection line and the second anode connection line are located on different sides of the anode connection via of the third pixel drive circuit.

In an exemplary implementation, the second anode connection line includes a first connection segment, a second connection segment and a third connection segment, the first connection segment and the third connection segment extend along a column direction, the second connection segment extends along a row direction, the first connection segment and the third connection segment are located on a same side of the second connection segment and electrically connected with the second connection segment, respectively; the first anode connection line includes a fourth connection segment and a fifth connection segment connected with each other and disposed at an acute angle, the fourth connection segment extends along the column direction;
an orthographic projection of the fourth connection segment of the first anode connection line on the base substrate is partially overlapped with the orthographic projections of the anode connection via of the first pixel drive circuit and the first electrode of the second light emitting device on the base substrate, an orthographic projection of the fifth connection segment of the first anode connection line on the base substrate is partially overlapped with the orthographic projection of the first electrode of the first light emitting device on the base substrate; an orthographic projection of the first connection segment of the second anode connection line on the base substrate is partially overlapped with the orthographic projection of the anode connection via of the second pixel drive circuit on the base substrate, an orthographic projection of the second connection segment of the second anode connection line on the base substrate is partially overlapped, or is not overlapped, with the orthographic projection of the first electrode of the third light emitting device on the base substrate; an orthographic projection of the third connection segment of the second anode connection line on the base substrate is partially overlapped with the orthographic projection of the first electrode of the second light emitting device on the base substrate;
the orthographic projection of the first anode connection line on the base substrate is not overlapped with the orthographic projection of the first electrode of the third light emitting device on the base substrate, and the first anode connection line and the second anode connection line are located on different sides of the anode connection via of the third pixel drive circuit.

In an exemplary implementation, (4a−3)-th column first pixel drive circuits are first pixel drive circuits, and (4a−1)-th column pixel drive circuits are second pixel drive circuits;
an orthographic projection of an anode connection via of a pixel drive circuit in a b-th row and a d-th column on the base substrate is partially overlapped with an orthographic projection of a first electrode of a light emitting device in the b-th row and the d-th column on the base substrate; an orthographic projection of an anode connection via of a pixel drive circuit in a c-th row and the d-th column on the base substrate is not overlapped with an orthographic projection of a first electrode of a light emitting device in the c-th row and the d-th column on the base substrate; the first anode connection line is electrically connected with a pixel drive circuit in the c-th row and the (4a−3)-th column and a first electrode in the c-th row and the (4a−1)-th column, respectively; the second anode connection line is electrically connected with a pixel drive circuit in the c-th row and the (4a−1)-th column and a first electrode in the c-th row and the (4a−3)-th column, respectively; wherein 1≤b≤N, and b is an odd number; 1≤c≤N, and c is an even number; 1≤d≤M, and d is an odd number, N is a total number of columns of the pixel drive circuits.

In an exemplary implementation, an area of the first electrode of the first light emitting device located in the odd-numbered row is larger than an area of the first electrode of the first light emitting device located in the even-numbered row, and an area of the first electrode of the second light emitting device located in the odd-numbered row is larger than an area of the first electrode of the second light emitting device located in the even-numbered row.

In an exemplary implementation, (4a−3)-th column first pixel drive circuits are second pixel drive circuits, and (4a−1)-th column pixel drive circuits are first pixel drive circuits;
an orthographic projection of an anode connection via of a pixel drive circuit in a c-th row and a d-th column on the base substrate is partially overlapped with an orthographic projection of a first electrode of a light emitting device in the c-th row and the d-th column on the base substrate; an orthographic projection of an anode connection via of a pixel drive circuit in a b-th row and the d-th column on the base substrate is not overlapped with an orthographic projection of a first electrode of a light emitting device in the b-th row and the d-th column on the base substrate; the first anode connection line is electrically connected with a pixel drive circuit in the b-th row and the (4a≤1)-th column and a first electrode in the b-th row and the (4a≤3)-th column, respectively; the second anode connection line is electrically connected with a pixel drive circuit in the b-th row and the (4a≤3)-th column and a first electrode in the b-th row and the (4a−1)-th column, respectively; wherein 1≤b≤N, and b is an odd number; 1≤c≤N, and c is an even number; 1≤d≤M, and d is an odd number, N is a total number of columns of the pixel drive circuits.

In an exemplary implementation, an area of the first electrode of the first light emitting device located in the even-numbered row is larger than an area of the first electrode of the first light emitting device located in the odd-numbered row, and an area of the first electrode of the second light emitting device located in the even-numbered row is larger than an area of the first electrode of the second light emitting device located in the odd-numbered row.

In an exemplary implementation, the base substrate further includes a second drive region, the first drive region includes a first side and a second side disposed oppositely, the second drive region is located on at least one of the first side and the second side of the first drive region, the second drive region is further provided with a gate drive circuit configured to provide a control signal to a pixel drive circuit, and a light emitting device;
at least one first anode connection line is electrically connected with a first pixel drive circuit located in the first drive region and a first electrode of at least one first light emitting device located in the second drive region, respectively; and at least one second anode connection line is electrically connected with a second pixel drive circuit located in the first drive region and a first electrode of at least one second light emitting device located in the second drive region, respectively.

In an exemplary implementation, when the orthographic projection of the first anode connection line on the base substrate is partially overlapped with the orthographic projection of the second anode connection line on the base substrate, the first anode connection line and the second anode connection line are disposed in different layers; and when the orthographic projection of the first anode connection line on the base substrate is not overlapped with the orthographic projection of the second anode connection line on the base substrate, the first anode connection line and the second anode connection line are disposed in different layers or in a same layer;
the first anode connection line includes a metal line or a transparent conductive line, and the second anode connection line includes a metal line or a transparent conductive layer.

In an exemplary implementation, the display substrate includes a driving structure layer and a light emitting structure layer which are provided on the base substrate, the driving structure layer is provided with a pixel drive circuit, a gate drive circuit and a data signal line, and the light emitting structure layer is provided with a light emitting device; the driving structure layer includes a first conductive layer, a second conductive layer and a third conductive layer sequentially stacked on the base substrate, and the light emitting structure layer includes a fourth conductive layer, an organic light emitting layer and a fifth conductive layer;
the third conductive layer includes, at least, source and drain electrodes of a plurality of transistors and a data signal line; and
the fourth conductive layer includes, at least, a first electrode of the light emitting device;
the first anode connection line is located in the third conductive layer or the fourth conductive layer, and the second anode connection line is located in the third conductive layer or the fourth conductive layer.

In an exemplary implementation, the third conductive layer is in a single-layer structure or a multi-layer structure;
when the third conductive layer is in the multi-layer structure, the third conductive layer includes a first sub-conductive layer and a second sub-conductive layer, or the third conductive layer includes a first sub-conductive layer, a second sub-conductive layer and a third sub-conductive layer, wherein the first sub-conductive layer and the second sub-conductive layer are metal conductive layers, and the third sub-conductive layer includes a metal conductive layer or a transparent conductive layer;
when the third sub-conductive layer is a transparent conductive layer, there is at least one third sub-conductive layer; and
when the third conductive layer is in the multi-layer structure, both the first anode connection line and the second anode connection line are located in at least one film of the third conductive layer.

In an exemplary implementation, the first light emitting device emits light in one color of red or blue, the second light emitting device emits light of the other color of red or blue, and the third light emitting device emits green light.

In a second aspect, the present disclosure also provides a display apparatus, including the display substrate described above.

Other aspects of the present disclosure may be comprehended after the drawings and the detailed descriptions are read and understood.

### BRIEF DESCRIPTION OF DRAWINGS

Accompanying drawings are intended to provide an understanding of technical solutions of the present application and form a part of the specification, and are used to explain the technical solutions of the present application together with embodiments of the present application, and do not constitute a limitation on the technical solutions of the present application.

FIG. 1 is a schematic diagram of a structure of a display apparatus.

FIG. 2 is a schematic diagram of a planar structure of a display substrate.

FIG. 3A is an equivalent circuit schematic of a pixel drive circuit.

FIG. 3B is a timing diagram illustrating operations of the pixel drive circuit in FIG. 3A.

FIG. 4A is an equivalent circuit diagram of another pixel drive circuit.

FIG. 4B is a timing diagram illustrating operations of the pixel drive circuit in FIG. 4A.

FIG. 5 is a first schematic diagram of a structure of a display substrate according to an embodiment of the present disclosure.

FIG. 6 is a second schematic diagram of a structure of a display substrate according to an embodiment of the present disclosure.

FIG. 7 is a first schematic cross-sectional view of a display substrate.

FIG. 8 is a second schematic cross-sectional view of a display substrate.

FIG. 9 is a third schematic cross-sectional view of a display substrate.

FIG. 10 is a fourth schematic cross-sectional view of a display substrate.

FIG. 11 is a fifth schematic cross-sectional view of a display substrate.

FIG. 12 is a sixth schematic cross-sectional view of a display substrate.

FIG. 13 is a seventh schematic cross-sectional view of a display substrate.

FIG. 14 is an eighth schematic cross-sectional view of a display substrate.

FIG. 15 is a ninth schematic cross-sectional view of a display substrate.

FIG. 16 is a schematic cross-sectional view of another display substrate.

FIG. 17 is a schematic cross-sectional view along an A-A direction in FIG. 7.

FIG. 18 is a schematic cross-sectional view along a B-B direction in FIG. 7.

### DETAILED DESCRIPTION

To make objectives, technical solutions, and advantages of the present disclosure clearer, the embodiments of the present disclosure will be described in detail below with reference to the accompanying drawings. It is to be noted that implementations may be implemented in multiple different forms. Those of ordinary skills in the art may easily understand such a fact that modes and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict. In order to keep following description of the embodiments of the present disclosure clear and concise, detailed description of part of known functions and known components are omitted in the present disclosure. The drawings of the embodiments of the present disclosure only involve structures involved in the embodiments of the present disclosure, and for other structures, reference may be made to conventional designs.

In the accompanying drawings, a size of each composition element, a thickness of a layer, or a region may be exaggerated sometimes for clarity. Therefore, an implementation of the present disclosure is not necessarily limited to the size, and a shape and a size of each component in the drawings do not reflect an actual scale. In addition, the accompanying drawings schematically illustrate ideal examples, and an implementation of the present disclosure is not limited to shapes, numerical values, or the like shown in the drawings.

Ordinal numerals “first”, “second”, “third”, etc., in the specification are set not to form limits in numbers but only to avoid confusion between constituent elements.

In the specification, for convenience, expressions “central”, “above”, “below”, “front”, “back”, “vertical”, “horizontal”, “top”, “bottom”, “inside”, “outside”, etc., for indicating directional or positional relationships are used to illustrate positional relationships between the constituent elements with reference to the accompanying drawings, not to indicate or imply that involved devices or elements are required to have specific orientations or are structured and operated in the specific orientations but only to easily describe the present specification and simplify the description, and thus should not be understood as limitations on the present disclosure. The positional relationships between the constituent elements may be changed as appropriate based on a direction according to which each constituent element is described. Therefore, appropriate replacements based on situations are allowed, which is not limited to the expressions in the specification.

In the specification, unless otherwise explicitly specified and defined, terms “mounting”, “coupling”, and “connection” should be understood in a broad sense. For example, it may be a fixed connection, or a detachable connection, or an integral connection; it may be a mechanical connection or an electrical connection; it may be a direct connection, or an indirect connection through a middleware, or an internal communication between two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first pole may be a drain electrode, and a second pole may be a source electrode. Or, the first pole may be a source electrode, and the second pole may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode” are interchangeable in the specification.

In the specification, an “electrical connection” includes a case that constituent elements are connected together through an element with a certain electrical action. The “element with a certain electrical effect” is not particularly limited as long as electrical signals between the connected constituent elements may be sent and received. Examples of the “element with a certain electrical action” not only include an electrode and a wiring, but also include a switching element such as a transistor, a resistor, an inductor, a capacitor, another element with various functions, etc.

In the specification, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 80° and below 100°, and thus may include a state in which the angle is above 85° and below 95°.

In the specification, a “film” and a “layer” are interchangeable. For example, a “conductive layer” may be replaced with a “conductive film” sometimes. Similarly, an “insulation film” may be replaced with an “insulation layer” sometimes.

In the specification, “disposed in a same layer” adopted refers to a structure formed by patterning two (or more than two) structures through a same patterning process, and their materials may be the same or different. For example, materials of precursors for forming multiple structures disposed in a same layer are the same, and final materials may be the same or different.

A triangle, rectangle, trapezoid, pentagon, or hexagon, etc. in the specification is not strictly defined, and it may be an approximate triangle, rectangle, trapezoid, pentagon, or hexagon, etc. There may be some small deformations caused by tolerance, and there may be a chamfer, an arc edge, deformation, etc.

In the present disclosure, “about” means that a boundary is not defined so strictly and numerical values within process and measurement error ranges are allowed.

FIG. 1 is a schematic diagram of a structure of a display apparatus. As shown in FIG. 1, the display apparatus may include a timing controller, a data signal driver, a scan signal driver and a pixel array. The pixel array may include a plurality of scan signal lines (Gate1 to GateN), a plurality of data signal lines (Data1 to DataL) and a plurality of pixel drive circuits Pxij.

In an exemplary implementation, the timing controller may provide the data signal driver with a gray scale value and a control signal which are suitable for a specification of the data signal driver, and provide the scan signal driver with a clock signal, a scan start signal, etc., which are suitable for a specification of the scan signal driver. The data signal driver may generate data voltages to be provided to data signal lines Data1, Data2, Data3, . . . , and DataL using the gray scale value and the control signal received from the timing controller. For example, the data signal driver may sample gray scale values using the clock signal and apply the data voltages corresponding to the gray scale values to the data signal lines Data1, Data2, Data3, . . . , and DataL by taking a row of sub-pixels as a unit, wherein n may be a natural number. The scan signal driver may generate scan signals to be provided to scan signal lines Gate1, Gate2, Gate3, . . . , and GateN by receiving a clock signal, a scan start signal, and the like from the timing controller. For example, the scan signal driver may sequentially provide a scan signal with an on-level pulse to the scan signal lines Gate1 to GateN. For example, the scan signal driver may be constructed in a form of a shift register, and generate the scan signals in a mode of sequentially transmitting the scan start signal provided in a form of on-level pulses to a next-stage circuit under control of the clock signal, wherein N may be a natural number. Each pixel drive circuit PXij may be connected to a corresponding data signal line and a corresponding scan signal line, in which i and j may be natural numbers.

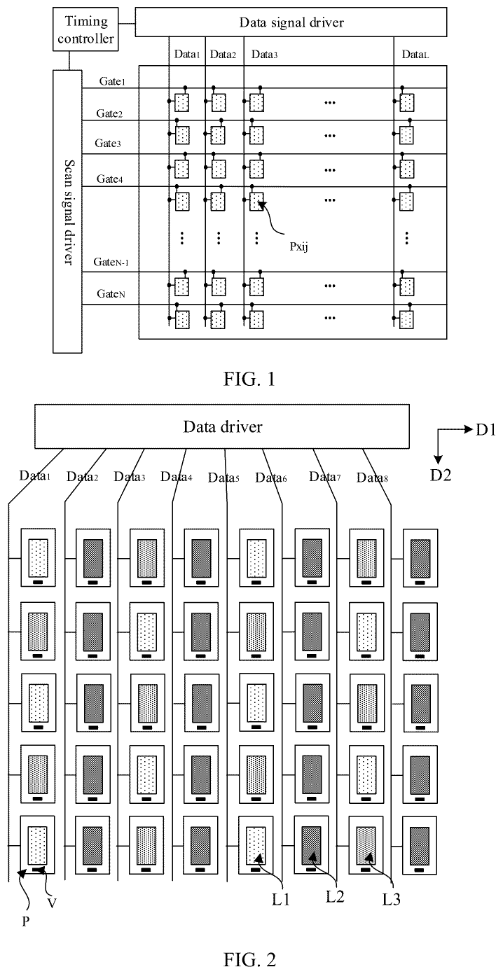

FIG. 2 is a schematic diagram of a planar structure of a display substrate. As shown in FIG. 2, the display substrate may include a plurality of circuit units P and a plurality of light emitting units arranged in a matrix, wherein the circuit unit includes a pixel drive circuit. At least one of the plurality of light emitting units includes a first light emitting device that emits light in a first color, a second light emitting device that emits light in a second color and a third light emitting device that emits light in a third color. The pixel drive circuit is connected with the scan signal line and the data signal line, respectively. The pixel drive circuit is configured to receive a data voltage transmitted through the data signal line to output a corresponding current to a connected light emitting device, under control of the scan signal line. The light emitting device is configured to emit light of a corresponding brightness in response to a current output by the pixel drive circuit connected to the light emitting unit.

In an exemplary implementation, the first light emitting device may emit red light, the second light emitting device may emit blue light, and the third light emitting device may emit green light.

In an exemplary implementation, as shown in FIG. 2, one light emitting unit may include four light emitting devices, which may include one first light emitting device, one second light emitting device, and two third light emitting devices. The four light emitting devices may be arranged in parallel in a horizontal direction, in parallel in a vertical direction, or in a square arrangement, which is not limited in the present disclosure. FIG. 2 illustrates an example in which four light emitting devices are arranged in a square arrangement. The arrangement of the four light emitting devices in FIG. 2 is referred to as a Bayer arrangement.

In an exemplary implementation, the light emitting device may be an Organic Light Emitting Diode (OLED), including a first electrode (anode), an organic light emitting layer, and a second electrode (cathode), which are stacked.

In an exemplary implementation, the organic light emitting layer may include a Hole Injection Layer (HIL), a Hole Transport Layer (HTL), an Electron Block Layer (EBL), an Emitting Layer (EML), a Hole Block Layer (HBL), an Electron Transport Layer (ETL), and an Electron Injection Layer (EIL) that are stacked. In an exemplary implementation, hole injection layers of all light emitting devices may be connected together to form a common layer, electron injection layers of all the light emitting elements may be connected together to form a common layer, hole transport layers of all the light emitting elements may be connected together to form a common layer, electron transport layers of all the light emitting elements may be connected together to form a common layer, hole block layers of all the light emitting elements may be connected together to form a common layer, emitting layers of adjacent light emitting elements may be overlapped slightly or may be isolated from each other, and electron block layers of adjacent light emitting elements may be overlapped slightly or may be isolated from each other.

In an exemplary implementation, the pixel drive circuit may have a structure of 3T1C, 4T1C, 5T1C, 5T2C, 6T1C, 7T1C, or 8T1C.

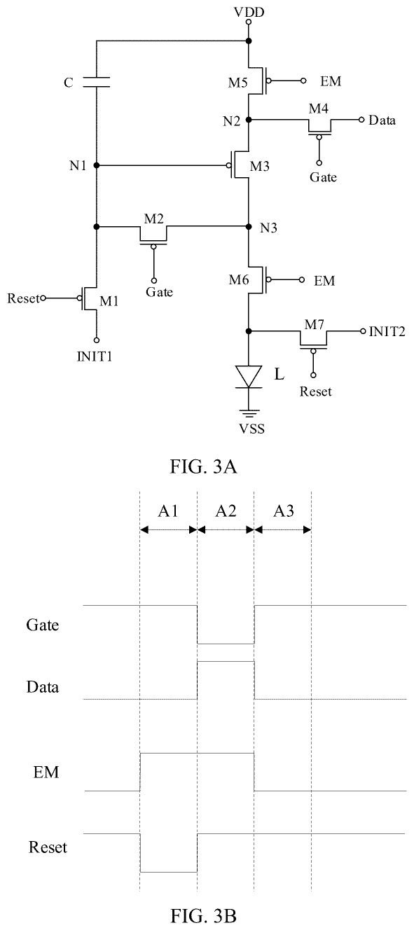

In an exemplary implementation, FIG. 3A is an equivalent circuit diagram of a pixel drive circuit. As shown in FIG. 3A, the pixel drive circuit may include seven transistors (a first transistor M1 to a seventh transistor M7), one capacitor C, and eight signal lines (a data signal line Data, a scan signal line Gate, a reset signal line Reset, a light emitting signal line EM, a first initial signal line INIT1, a second initial signal line INIT2, a high-level power supply line VDD, and a low-level power supply line VSS).

In an exemplary implementation, as shown in FIG. 3A, a first plate of the capacitor C is connected with the high-level power supply line VDD and a second plate of the capacitor C is connected with a first node N1. A control electrode of the first transistor M1 is connected with the reset signal line Reset, a first electrode of the first transistor M1 is connected with the first initial signal line INIT1, and a second electrode of the first transistor is connected with the first node N1; a control electrode of the second transistor M2 is connected with the scan signal line Gate, a first electrode of the second transistor M2 is connected with the first node N1, and a second electrode of the second transistor M2 is connected with a second node N2. A control electrode of the third transistor M3 is connected with the first node N1, a first electrode of the third transistor M3 is connected with a second node N2, and a second electrode of the third transistor M3 is connected with the third node N3. A control electrode of the fourth transistor M4 is connected with the scan signal line GATE, a first electrode of the fourth transistor M4 is connected with the data signal line Data, and a second electrode of the fourth transistor M4 is connected with the second node N2. A control electrode of the fifth transistor M5 is connected with the light emitting signal line EM, a first electrode of the fifth transistor M5 is connected with the high-level power supply line VDD, and a second electrode of the fifth transistor M5 is connected with the second node N2. A control electrode of the sixth transistor M6 is connected with the light emitting signal line EM, a first electrode of the sixth transistor M6 is connected with the third node N3, and a second electrode of the sixth transistor M6 is connected with a first electrode of a light emitting device L. A control electrode of the seventh transistor M7 is connected to the reset signal line Reset or the scan signal line Gate, a first electrode of the seventh transistor M7 is connected to the second initial signal line INIT2, a second electrode of the seventh transistor M7 is connected to the first electrode of the light emitting device L, and a second electrode of the light emitting device is connected to the low-level power supply line VSS. FIG. 3A is illustrated by taking the control electrode of the seventh transistor M7 and the reset signal line Reset as an example.

In an exemplary implementation, a signal of the high-level power supply line VDD is a high-level signal continuously provided, and a signal of the low-level power supply line VSS is a low-level signal.

Transistors may be classified as N-type transistors and P-type transistors according to characteristics of the transistors. When a transistor is a P-type transistor, its turn-on voltage is a low-level voltage (e.g., 0V, −5 V, −10 V, or another suitable voltage), and its turn-off voltage is a high-level voltage (e.g., 5 V, 10 V, or another suitable voltage). When a transistor is an N-type transistor, its turn-on voltage is a high-level voltage (e.g., 5 V, 10 V, or another suitable voltage), and its turn-off voltage is a low-level voltage (e.g., 0 V, −5 V, −10 V, or another suitable voltage).

In an exemplary implementation, the first transistor M1 to the seventh transistor M7 may be P-type transistors, or may be N-type transistors. Same type of transistors in the pixel drive circuit may simplify a process flow, reduce a process difficulty of the display panel, and improve a yield of a product. In some possible implementations, the first transistor M1 to the seventh transistor M7 may include a P-type transistor and an N-type transistor.

In an exemplary implementation, for the first transistor M1 to the seventh transistor M7, low temperature poly silicon thin film transistors may be used, or oxide thin film transistors may be used, or both a low temperature poly silicon thin film transistor and an oxide thin film transistor may be used. An active layer of a low temperature poly silicon thin film transistor is made of Low Temperature Poly Silicon (LTPS), and an active layer of an oxide thin film transistor is made of an oxide semiconductor (Oxide). A Low temperature poly silicon thin film transistor has advantages such as a high migration rate and fast charging, and an oxide thin film transistor has advantages such as a low leakage current. The low temperature poly silicon thin film transistor and the oxide thin film transistor are integrated on one display substrate to form a Low Temperature Polycrystalline Oxide (LTPO) display substrate, so that advantages of both the low temperature poly silicon thin film transistor and the oxide thin film transistor may be utilized, low-frequency drive may be achieved, power consumption may be decreased, and display quality may be improved.

In an exemplary implementation, when the display substrate is an LTPO display substrate, the first transistor T1 and the second transistor T2 may be N-type transistors, and remaining transistors are P-type transistors. When the display substrate is an LTPS display substrate, the first transistor M1 to the seventh transistor M7 are P-type transistors.

FIG. 3B is a timing diagram illustrating operations of the pixel drive circuit in FIG. 3A, and FIG. 3B illustrates an example in which all the transistors in FIG. 3A are P-type transistors. An exemplary embodiment of the present disclosure is described below with reference to an operating process of the pixel drive circuit illustrated in FIG. 3B. In an exemplary implementation, an operating process of the pixel drive circuit may include following stages.

In a first stage A1, referred to as a reset stage, signals of the scan signal line Gate and the light emitting signal line EM are high-level signals, and a signal of the reset signal line Reset is a low-level signal. The signal of the reset signal line Reset is the high-level signal, the first transistor M1 is turned on, a signal of the first initial signal line INIT1 is provided to the first node N1 to initialize the capacitor C and clear an original data voltage in the capacitor C, the seventh transistor M7 is turned on, an initial voltage of the second initial signal line INIT2 is provided to the first electrode of the light emitting device L, to initialize (reset) the first electrode of the light emitting device L and empty a pre-stored voltage therein, and initialization is completed. The signals of the scan signal line Gate and the light emitting signal line EM are high-level signals, the second transistor M2, the fourth transistor M4, the fifth transistor M5, and the sixth transistor M6 are turned off, and the light emitting device L does not emit light in this stage.

In a second stage A2, referred to as a data writing stage or a threshold compensation stage, the scan signal line Gate is a low-level signal, signals of the light emitting signal line EM and the reset signal line Reset are high-level signals, and the data signal line Data outputs a data voltage. In this stage, since the first node N1 is a low-level signal, the third transistor M3 is turned on. The signal of the scan signal line Gate is the low-level signal, the second transistor T2 and the fourth transistor M4 are turned on, the second transistor M2 and the fourth transistor M4 are turned on, so that a data voltage output by the data signal line Data is provided to the first node N1 through the second node N2, the turned-on third transistor M3, the second node N3, and the turned-on second transistor M2, and a difference between the data voltage output by the data signal line Data and a threshold voltage of the third transistor M3 is charged into the capacitor C until a voltage of the first node N1 is Vd−|Vth|, Vd is the data voltage output by the data signal line Data, Vth is the threshold voltage of the third transistor M3, ensuring that the light emitting device L does not emit light. A signal of the reset signal line Reset is a high-level signal, and the first transistor M1 is turned off. A signal of the light emitting signal line EM is a high-level signal, and the fifth transistor M5 and the sixth transistor M6 are turned off.

In a third stage A3, referred to as a light emitting stage, signals of the scan signal line Gate and the reset signal line Reset are high-level signals, and a signal of the light emitting signal line EM is a low-level signal. The signal of the light emitting signal line EM is the low-level signal, the fifth transistor M5 and the sixth transistor M6 are turned on, and a power supply voltage output by the high-level power supply line VDD provides a drive voltage to the first electrode of the light emitting device L through the turned-on fifth transistor M5, the third transistor M3, and the sixth transistor M6, to drive the light emitting device L to emit light.

In a drive process of the pixel drive circuit, a drive current flowing through the third transistor M3 (drive transistor) is determined by a voltage difference between the control electrode and the first electrode. Since the voltage of the first node N1 is Vd−|Vth|, the driving current of the third transistor M3 is as follows:

$$I = K * {( Vgs - Vth )}^{2} = K * {[ ( Vdd - Vd + \vert Vth \vert ) - Vth ]}^{2} = K * {( Vdd - Vd )}^{2}$$

Herein, I is the drive current flowing through the third transistor M3, i.e., a drive current for driving the light emitting device L, K is a constant, Vgs is the voltage difference between the control electrode and the first electrode of the third transistor M3, Vth is the threshold voltage of the third transistor M3, Vd is the data voltage output by the data signal line Data, and Vdd is the power voltage output by the high-level power supply line VDD.

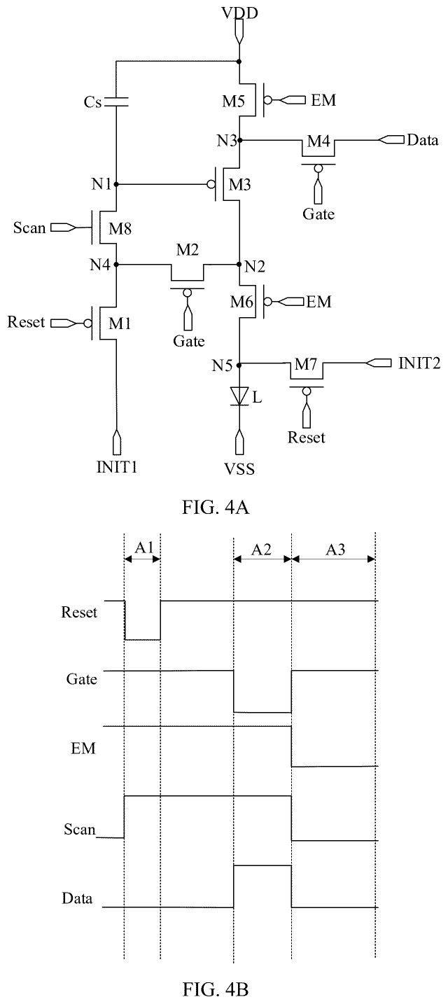

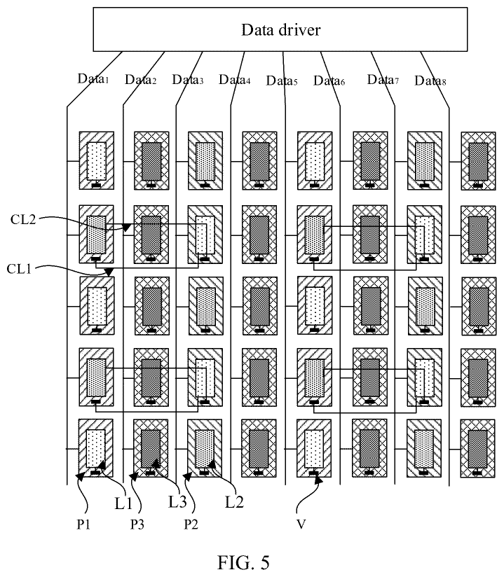

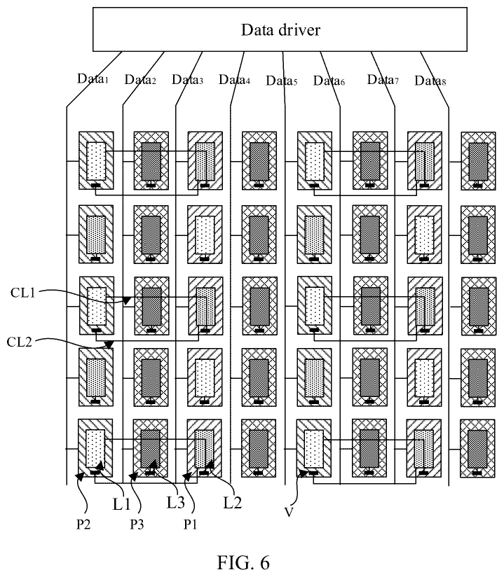

In an exemplary implementation, FIG. 4A is an equivalent circuit diagram of another pixel drive circuit. As shown in FIG. 4A, the pixel drive circuit may include eight transistors (a first transistor M1 to an eighth transistor M8), one capacitor C, and nine signal lines (a data signal line Data, a control signal line Scan, a scan signal line Gate, a reset signal line Reset, a light emitting signal line EM, a first initial signal line INIT1, a second initial signal line INIT2, a high-level power supply line VDD, and a low-level power supply line VSS).

In an exemplary implementation, the pixel drive circuit in FIG. 4A is suitable for an LTPO display substrate.

In an exemplary implementation, a first plate of the capacitor C is connected with the high-level power supply line VDD, and a second plate of the capacitor C is connected with a first node N1. A control electrode of the first transistor M1 is connected with the reset signal line Reset, a first electrode of the first transistor M1 is connected with the first initial signal line INIT1, and a second electrode of the first transistor is connected with a fourth node N4. A control electrode of the second transistor M2 is connected with the scan signal line Gate, a first electrode of the second transistor M2 is connected with the fourth node N4, and a second electrode of the second transistor M2 is connected with a second node N2. A control electrode of the third transistor M3 is connected with the first node N1, a first electrode of the third transistor M3 is connected with a second node N2, and a second electrode of the third transistor M3 is connected with the third node N3. A control electrode of the fourth transistor M4 is connected with the scan signal line Gate, a first electrode of the fourth transistor M4 is connected with the data signal line Data, and a second electrode of the fourth transistor M4 is connected with the third node N3. A control electrode of the fifth transistor M5 is connected with the light emitting signal line EM, a first electrode of the fifth transistor M5 is connected with the high-level power supply line VDD, and a second electrode of the fifth transistor M5 is connected with the third node N3. A control electrode of the sixth transistor M6 is connected with the light emitting signal line EM, a first electrode of the sixth transistor M6 is connected with the second node N2, and a second electrode of the sixth transistor M6 is connected with a first electrode of a light emitting device L. A control electrode of the seventh transistor M7 is connected with the reset signal line Reset, a first electrode of the seventh transistor M7 is connected with the second initial signal line INIT2, a second electrode of the seventh transistor M7 is connected with the first electrode of the light emitting device L, and a second electrode of the light emitting device L is connected with the low-level power supply line VSS. A control electrode of the eighth transistor M8 is connected with the control signal line SCAN, a first electrode of the eighth transistor M8 is connected with the first node N1, and a second electrode of the eighth transistor M8 is connected with the fourth node N4.

In an exemplary implementation, the control electrode of the seventh transistor M7 may also be connected with the scan signal line Gate, the first electrode of the seventh transistor M7 is connected with the second initial signal line INIT2, the second electrode of the seventh transistor M7 is connected with the first electrode of the light emitting device L, and the second electrode of the light emitting device L is connected with the low-level power supply line VSS.

In an exemplary implementation, a signal of the high-level power supply line VDD is a high-level signal continuously provided, and a signal of the low-level power supply line VSS is a low-level signal.

In an exemplary implementation, the eighth transistor M8 is a metal oxide transistor, and is an N-type transistor, and the first transistor M1 to the seventh transistor M7 are low temperature poly silicon transistors and are P-type transistors.

In an exemplary implementation, the eighth transistor M8 is an oxide transistor and may reduce a leakage current, improve performance of the pixel drive circuit, and may reduce power consumption of the pixel drive circuit.

FIG. 4B is a timing diagram illustrating operations of the pixel drive circuit in FIG. 4A. An exemplary embodiment of the present disclosure is described below with reference to an operating process of the pixel drive circuit illustrated in FIG. 4B. The operating process of the pixel drive circuit may include following stages.

In a first stage A1, referred to as a reset stage, signals of the control signal line Scan, the light emitting signal line EM, and the scan signal line Gate are all high-level signals, and a signal of the reset signal line Reset is a low-level signal. The signal of the reset signal line Reset is the low-level signal, the first transistor M1 is turned on, a signal of the first initial signal line INIT1 is provided to the fourth node N4, the seventh transistor M7 is turned on, an initial voltage of the second initial signal line INIT2 is provided to the first electrode of the light emitting device L to initialize (reset) the first electrode of the light emitting device L, for example, empty a pre-stored voltage therein, initialization is completed, and the light emitting device L is ensured not to emit light. A signal of the control signal line Scan is a high-level signal, the eighth transistor M8 is turned on, a signal of the fourth node N4 is provided to the first node N1 to initialize the capacitor C, and an original data voltage in the capacitor C is cleared. Signals of the scan signal line Gate and the light emitting signal line EM are high-level signals, and the second transistor M2, the fourth transistor M4, the fifth transistor M5, the sixth transistor M6, and the seventh transistor M7 are turned off, and the light emitting device L does not emit light in this stage.

In a second stage A2, referred to as a data writing stage or a threshold compensation stage, a signal of the scan signal line Gate is a low-level signal, signals of the reset signal line Reset, the light emitting signal line EM, and the control signal line Scan are high-level signals, and the data signal line Data outputs a data voltage. In this stage, since the first node N1 is a low-level signal, the third transistor M3 is turned on. The signal of the scan signal line Gate is the low-level signal, the second transistor M2 and the fourth transistor M4 are turned on, a signal of the control signal line Scan is a high-level signal, and the eighth transistor M8 is turned on. The second transistor M2, the fourth transistor M4, and the eighth transistor M8 are turned on so that a data voltage output by the data signal line Data is provided to the first node N1 through the third node N3, the turned-on third transistor M3, the second node N2, the turned-on second transistor M2, the fourth node N4, and the turned-on eighth transistor M8. A difference between the data voltage output by the data signal line Data and a threshold voltage of the third transistor M3 is charged into the capacitor C until a voltage of the first node Nl is Vd−|Vth|, wherein Vd is the data voltage output by the data signal line Data, and Vth is the threshold voltage of the third transistor M3. A signal of the reset signal line Reset is a low-level signal, and the first transistor M1 and the seventh transistor M7 are turned off. A signal of the light emitting signal line EM is a high-level signal, and the fifth transistor M5 and the sixth transistor M6 are turned off.

In a third stage A3, referred to as a light emitting stage, signals of the control signal line Scan and the light emitting signal line EM are both low-level signals, and signals of the scan signal line Gate and the reset signal line Reset are high-level signals. A signal of the reset signal line Reset is a low-level signal, and the first transistor M1 and the seventh transistor M7 are turned off. A signal of the control signal line Scan is a low-level signal, the signals of the scan signal line Gate and the reset signal line Reset are the high-level signals, and the second transistor M2, the fourth transistor M4, and the eighth transistor M8 are turned off. A signal of the light emitting signal line EM is a low-level signal, the fifth transistor M5 and the sixth transistor M6 are turned on, and a power supply voltage output by the high-level power supply terminal VDD provides a drive voltage to the first electrode of the light emitting device L through the turned-on fifth transistor M5, the third transistor M3, and the sixth transistor M6, so as to drive the light emitting device L to emit light.

In a drive process of the pixel drive circuit, a drive current flowing through the third transistor M3 (drive transistor) is determined by a voltage difference between the control electrode and the first electrode. Since the voltage of the first node N1 is Vd−|Vth|, the driving current of the third transistor M3 is as follows:

$$I = K * {( Vgs - Vth )}^{2} = K * {[ ( Vdd - Vd + \vert Vth \vert ) - Vth ]}^{2} = K * {( Vdd - Vd )}^{2}$$

where I is the drive current flowing through the third transistor M3, that is, a drive current for driving the light emitting device L, K is a constant, Vgs is the voltage difference between the control electrode and the first electrode of the third transistor M3, Vth is the threshold voltage of the third transistor M3, Vd is the data voltage output by the data signal line Data, and Vdd is the power supply voltage output by the high-level power supply terminal VDD.

With development of display technologies, the sub-pixel arrangement design of the Bayer arrangement has become a commonly used design of mainstream products. As shown in FIG. 2, an odd-numbered column data signal line is electrically connected with a pixel drive circuit that drives a first light emitting device and a pixel drive circuit that drives a second light emitting device, so that when the display product displays a red and blue solid color picture, a driver that supplies a signal to the data signal line switches between a first color data signal and a second color data signal at a high frequency, resulting in higher power consumption of the display product.

FIG. 5 is a first schematic diagram of a structure of a display substrate according to an embodiment of the present disclosure, and FIG. 6 is a second schematic diagram of a structure of a display substrate according to an embodiment of the present disclosure. As shown in FIGS. 5 and 6, the display substrate according to the embodiments of the present disclosure may include a based substrate, pixel drive circuits in a plurality of rows and columns, light emitting devices in a plurality of rows and columns, a plurality of data signal lines Data, and a plurality of anode connection lines, which are disposed on the base substrate, wherein the pixel drive circuit is connected with the data signal line and the light emitting device, respectively. The light emitting device include a first light emitting device L1, a second light emitting device L2 and a third light emitting device L3. A plurality of first light emitting devices L1 and a plurality of second light emitting devices L2 are alternately arranged along a column direction, a plurality of third light emitting devices L3 are arranged along the column direction, and the light emitting device includes a first electrode. FIGS. 5 and 6 illustrate anode connection lines CL1 and CL2 as an example. In FIGS. 5 and 6, only a first drive region is shown.

In an exemplary implementation, as shown in FIGS. 5 and 6, in the first drive region, a light emitting device in an n-th row and a (4a−3)-th column is a first light emitting device, a light emitting device in the n-th row and a (4a−1)-th column is a second light emitting device, a light emitting device in an (n+1)-th row and the (4a−3)-th column is a second light emitting device, a light emitting device in the (n+1)-th row and the (4a−1)-th column is a first light emitting device, and a light emitting device in an even-numbered column is a third light emitting device, wherein 1≤a≤M/4, 1≤n≤N−1, M is a total number of columns of light emitting devices or pixel drive circuits in the first drive region, and is an even number, N is a total number of rows of light emitting devices or pixel drive circuits in the first drive region.

In an exemplary implementation, as shown in FIGS. 5 and 6, a pixel drive circuit in one of the odd-numbered column and the even-numbered column is electrically connected with the first electrode of the first light emitting device or the second light emitting device through the anode connection line, and a pixel drive circuit in the other of the odd-numbered column and the even-numbered column is electrically connected with the first electrode of the third light emitting device. FIGS. 5 and 6 are illustrated by taking the pixel drive circuit in the odd-numbered column which is electrically connected with the first electrode of the first light emitting device or the second light emitting device through the anode connection line, and the pixel drive circuit in the other of the even-numbered column which is electrically connected with the first electrode of the third light emitting device as an example.

In an exemplary implementation, as shown in FIGS. 5 and 6, an orthographic projection of a first electrode of a light emitting device connected to a pixel drive circuit in the n-th row and a (2f−1)-th column on the base substrate is partially overlapped with an orthographic projection of a region where a pixel drive circuit in the n-th row and a (2f+1)-th column is located on the base substrate, an orthographic projection of a first electrode of a light emitting device connected to the pixel drive circuit in the n-th row and the (2f+1)-th column on the base substrate is partially overlapped with an orthographic projection of a region where a pixel drive circuit in the n-th row and a (2f−1)-th column is located on the base substrate, and an orthographic projection of a first electrode of a light emitting device connected to a pixel drive circuit in the n-th row and an even-numbered column on the base substrate is partially overlapped with an orthographic projection of a region where the pixel drive circuit in the n-th row and the even-numbered column is located on the base substrate, wherein 1≤f≤M/2, and f is an odd. For example, when M=8, f=1 or 3, and pixel drive circuits in a first row are taken as an example, an orthographic projection of a first electrode of a light emitting device connected to a pixel drive circuit in the first row and a first column on the base substrate is partially overlapped with an orthographic projection of a region where a pixel drive circuit in the first row and a third column is located on the base substrate, an orthographic projection of a first electrode of a light emitting device connected to the pixel drive circuit in the first row and the third column on the base substrate is partially overlapped with an orthographic projection of a region where the pixel drive circuit in the first row and first column is located on the base substrate, an orthographic projection of a first electrode of a light emitting device connected to a pixel drive circuit in the first row and a fifth column on the base substrate is partially overlapped with an orthographic projection of a region where a pixel drive circuit in the first row and a seventh column is located on the base substrate, an orthographic projection of a first electrode of a light emitting device connected to the pixel drive circuit in the first row and the seventh column on the base substrate is partially overlapped with an orthographic projection of a region where the pixel drive circuit in the first row and the fifth column is located on the base substrate, an orthographic projection of a first electrode of a light emitting device connected to a pixel drive circuit in the first row and a second column on the base substrate is partially overlapped with an orthographic projection of a region where the pixel drive circuit in the first row and the second column is located on the base substrate, an orthographic projection of a first electrode of a light emitting device connected to a pixel drive circuit in the first row and a fourth column on the base substrate is partially overlapped with an orthographic projection of a region where the pixel drive circuit in the first row and the fourth column is located on the base substrate, and so on.

In an exemplary implementation, a based substrate may be a rigid substrate or a flexible substrate, wherein the rigid substrate may be, but is not limited to, one or more of glass and metal foil; the flexible substrate may be, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fiber.

In an exemplary implementation, as shown in FIGS. 5 and 6, in the first drive region, a light emitting device in an odd-numbered row and the (4a−3)-th column is the first light emitting device L1, a light emitting device in the odd-numbered row and the (4a−1)-th column is the second light emitting device L2, a light emitting device in an even-numbered row and the (4a−3)-th column is the second light emitting device L2, a light emitting device in the odd-numbered row and the (4a−1)-th column is the first light emitting device L1, and a light emitting device in an even-numbered column is a third light emitting device L3, wherein 1≤a≤M/4, and M is a total number of columns of the light emitting devices, which is an even number. For example, all the light emitting devices in the odd-numbered rows are arranged in a same manner. Taking the first row as an example, all of a light emitting device in the first row and the first column, a light emitting device in the first row and the fifth column, a light emitting device in the first row and a ninth column, and the like are first light emitting devices, and all of a light emitting device in the first row and the third column, a light emitting device in the first row and the seventh column, a light emitting device in the first row and an eleventh column, and the like are second light emitting devices. All light emitting devices in the even-numbered row are arranged in a same manner. Taking the second row as an example, all of a light emitting device in the second row and the first column, a light emitting device in the second row and the fifth column, a light emitting device in the second row and the ninth column, and the like are the second light emitting devices, and all of a light emitting device in the second row and the third column, a light emitting device in the second row and the seventh column, a light emitting device in the second row and the eleventh column, and the like are the first light emitting devices in the second row.

In an exemplary implementation, pixel drive circuits in a column may be electrically connected with at least one data signal line. FIGS. 5 and 6 illustrate pixel drive circuits in one column electrically connecting to one data signal line, and illustrate a first data signal line Data1 to an eighth data signal line Data8, only.

In an exemplary implementation, pixel drive circuit in one of the odd-numbered column and the even-numbered column is electrically connected with the first light emitting devices or the second light emitting devices through the anode connection line, so that a data signal line connected to the pixel drive circuit in the one of the odd-numbered column and the even-numbered column only supplies a first color data signal or a second color data signal. The data signal line connected to the pixel drive circuits in the one of the odd-numbered column and the even-numbered column supplies the first color data signal when the pixel drive circuit in the one of the odd-numbered column and the even-numbered column is electrically connected with the first light emitting devices, and the data signal line connected to the pixel drive circuits in the one of the odd-numbered column and the even-numbered column supplies the second color data signal when the pixel drive circuit in the one of the odd-numbered column and the even-numbered column is electrically connected with the second light emitting devices. Pixel drive circuits in the other of the odd-numbered column and the even-numbered column are electrically connected with the third light emitting device, such that the data signal line connected to the pixel drive circuits in the other of the odd-numbered column and the even-numbered column supplies a third color data signal, only.

In an exemplary implementation, the display substrate is further electrically connected with a data driver configured to supply signals to the data signal lines. Since the pixel drive circuits in one of the odd-numbered column and the even-numbered column are electrically connected with the first light emitting device or the second light emitting device through the anode connection line, and the pixel drive circuits in the other of the odd-numbered column and the even-numbered column are electrically connected with the third light emitting device, the data signal lines continuously supply a same color data signal regardless of pictures displayed on the display substrate. That is, the data driver supplying the signal to the data signal lines is not needed to switch between different color data signals at a high frequency.

A display substrate according to an embodiment of the present disclosure includes a based substrate, pixel drive circuits in a plurality of rows and columns, light emitting devices in a plurality of rows and columns, a plurality of data signal lines, and a plurality of anode connection lines, which are disposed on the base substrate, wherein the base substrate includes a first drive region where the pixel drive circuit and the data signal lines are located, and where the light emitting devices and the anode connection lines are at least partially located. The pixel drive circuit is connected with the data signal line and the light emitting device. The light emitting devices include a first light emitting device, a second light emitting device and a third light emitting device. A plurality of first light emitting devices and a plurality of second light emitting devices are alternately arranged along a column direction, and a plurality of third light emitting devices are arranged along the column direction. The light emitting device includes a first electrode. In the first drive region, a light emitting device in an n-th row and a (4a−3)-th column is the first light emitting device, a light emitting device in the n-th row and a (4a−1)-th column is the second light emitting device, a light emitting device in an (n+1)-th row and the (4a−3)-th column is the second light emitting device, a light emitting device in the (n+1)-th row and the (4a−1)-th column is the first light emitting device, and light emitting devices in an even-numbered column are third light emitting devices; wherein 1≤a≤M/4, 1≤n≤N−1, wherein M is a total number of columns of light emitting devices or pixel drive circuits in the first drive region, and is an even number. N is a total number of rows of light emitting devices or pixel drive circuits in the first drive region. A pixel drive circuit in one of the odd-numbered column and the even-numbered column is electrically connected with the first electrode of the first light emitting device or the second light emitting device through the anode connection line, and a pixel drive circuit in the other of the odd-numbered column and the even-numbered column is electrically connected with the first electrode of the third light emitting device. An orthographic projection of a first electrode of a light emitting device connected to a pixel drive circuit in the n-th row and a (2f−1)-th column on the base substrate is partially overlapped with an orthographic projection of a region where a pixel drive circuit in the n-th row and a (2f+1)-th column is located on the base substrate, an orthographic projection of a first electrode of a light emitting device connected to the pixel drive circuit in the n-th row and the (2f+1)-th column on the base substrate is partially overlapped with an orthographic projection of a region where a pixel drive circuit in the n-th row and a (2f−1)-th column is located on the base substrate, and an orthographic projection of a first electrode of a light emitting device connected to a pixel drive circuit in the n-th row and an even-numbered column on the base substrate is partially overlapped with an orthographic projection of a region where the pixel drive circuit in the n-th row and the even-numbered column is located on the base substrate, wherein 1≤f≤M/2, and f is an odd. In the present disclosure, pixel drive circuit in one of the odd-numbered column and the even-numbered column is electrically connected with the first electrode of the first light emitting device or the second light emitting device through the anode connection line, and a pixel drive circuit in the other of the odd-numbered column and the even-numbered column is electrically connected with the first electrode of the third light emitting device, so that when the display product displays a red and blue solid color picture, the data driver that supplies a data signal may be not needed to switch between different data signals at a high frequency, reducing power consumption of the display product, and improving reliability of the display product.

In an exemplary implementation, the first light emitting device emits light in one color of red or blue, the second light emitting device emits light of the other color of red or blue, and the third light emitting device emits green light.

In an exemplary implementation, as shown in FIGS. 5 and 6, the pixel drive circuit is provided with an anode connection via V, and the first electrode of the light emitting device is electrically connected with the pixel drive circuit through the anode connection via.

In an exemplary implementation, the anode connection via is configured as a via exposing the second electrode of the sixth transistor (also known as the second electrode of the seventh transistor) in the pixel drive circuit in FIGS. 3A and 4A. At least one anode connection line is connected with the second electrode of the sixth transistor (also known as the second electrode of the seventh transistor) in the pixel drive circuit through the anode connection via.

In an exemplary implementation, the display substrate further includes a transfer hole configured to expose the anode connection line. For example, a first electrode of at least one light emitting device is electrically connected with the anode connection line through the transfer hole.

In an exemplary implementation, as shown in FIGS. 5 and 6, the pixel drive circuit includes a first pixel drive circuit P1 configured to drive the first light emitting device L1 to emit light, a second pixel drive circuit P2 configured to drive the second light emitting device L2 to emit light, and a third pixel drive circuit P3 configured to drive the third light emitting device L3 to emit light. The odd-numbered column pixel drive circuit is the first pixel drive circuit or the second pixel drive circuit, and the even-numbered column pixel drive circuit is the third pixel drive circuit.

In an exemplary implementation, as shown in FIGS. 5 and 6, a d-th column pixel drive circuit is one of the first pixel drive circuit and the second pixel drive circuit, and a (d+2)-th column pixel drive circuit is the other of the first pixel drive circuit and the second pixel drive circuit, wherein 1≤d≤M, and d is an odd number. For example, when the first column pixel drive circuit is the first pixel drive circuit, the third column pixel drive circuit is the second pixel drive circuit, the fifth column pixel drive circuit is the first pixel drive circuit, the seventh column pixel drive circuit is the second pixel drive circuit, and so on. When the first column pixel drive circuit is the second pixel drive circuit, the third column pixel drive circuit is the first pixel drive circuit, the fifth column pixel drive circuit is the second pixel drive circuit, the seventh column pixel drive circuit is the first pixel drive circuit, and so on.

In an exemplary implementation, an orthographic projection of a first electrode of at least one first light emitting device L1 on the base substrate is partially overlapped with an orthographic projection of an anode connection line to which the first light emitting device L1 is connected on the base substrate, and the orthographic projection of the first electrode of the at least one first light emitting device L1 on the base substrate is not overlapped with an orthographic projection of an anode connection via V of the first pixel drive circuit P1 to which the first light emitting device L1 is connected on the base substrate.

In an exemplary implementation, an orthographic projection of a first electrode of at least one second light emitting device L2 on the base substrate is partially overlapped with an orthographic projection of an anode connection line to which the second light emitting device L2 is connected on the base substrate, and the orthographic projection of the first electrode of the at least one second light emitting device L2 on the base substrate is not overlapped with an orthographic projection of an anode connection via V of the second pixel drive circuit P2 to which the second light emitting device L2 is connected on the base substrate.

In an exemplary implementation, an orthographic projection of a first electrode of the third light emitting device L3 on the base substrate is partially overlapped with an orthographic projection of an anode connection via V of the third pixel drive circuit P3 to which the third light emitting device L3 is connected on the base substrate.

In an exemplary implementation, as shown in FIGS. 5 and 6, the anode connection line may include a first anode connection line CL1 and a second anode connection line CL2.

In an exemplary implementation, the first anode connection line CL1 is electrically connected with a part of the first pixel drive circuits, and with a first electrode of a first light emitting device to which the part of the first pixel drive circuits is connected, respectively. An orthographic projection of the first anode connection line CL1 on the base substrate is partially overlapped with an orthographic projection of an anode connection via of the connected first pixel drive circuit on the base substrate, and is partially overlapped with an orthographic projection of the first electrode of the connected first light emitting device on the base substrate.

In an exemplary implementation, the second anode connection line CL2 is electrically connected with a part of the second pixel drive circuits, and with a first electrode of a second light emitting device to which the part of the second pixel drive circuits is connected, respectively. An orthographic projection of the second anode connection line CL2 on the base substrate is partially overlapped with an orthographic projection of an anode connection via of the connected second pixel drive circuit on the base substrate, and is partially overlapped with an orthographic projection of the first electrode of the connected second light emitting device on the base substrate.

In an exemplary implementation, as shown in FIG. 5, the (4a−3)-th column pixel drive circuits belong to the first pixel drive circuit P1, and the (4a−1)-th column pixel drive circuits belong to the second pixel drive circuit P2. For example, the first column pixel drive circuit, the fifth column pixel drive circuit, the ninth column pixel drive circuit and the like belong to the first pixel drive circuit P1, and the second column pixel drive circuit, the fifth column pixel drive circuit, the ninth column pixel drive and the like belong to the second pixel drive circuit P2.

In an exemplary implementation, as shown in FIG. 5, an orthographic projection of an anode connection via V of a pixel drive circuit in a b-th row and a d-th column on the base substrate is partially overlapped with an orthographic projection of a first electrode of a light emitting device in the b-th row and the d-th column on the base substrate, wherein 1≤b≤N, and b is an odd number, 1≤d≤M, and d is an odd number, and N is a total number of columns of the pixel drive circuits. That is, an orthographic projection of an anode connection via V of a pixel drive circuit in any odd-numbered row and any odd-numbered column on the base substrate is partially overlapped with an orthographic projection of a first electrode of a light emitting device in any odd-numbered row and any odd-numbered column on the base substrate. For example, an orthographic projection of an anode connection via V in a first row and a first column on the base substrate is partially overlapped with an orthographic projection of a first electrode of a light emitting device in the first row and the first column on the base substrate, an orthographic projection of an anode connection via V in the first row and a third column on the base substrate is partially overlapped with an orthographic projection of a first electrode of a light emitting device in the first row and the third column on the base substrate, and so on.

In an exemplary implementation, as shown in FIG. 5, an orthographic projection of an anode connection via V of a pixel drive circuit in a c-th row and the d-th column on the base substrate is not overlapped with an orthographic projection of a first electrode of a light emitting device in the c-th row and the d-th column on the base substrate, wherein 1≤c≤N, and c is an even number. That is, an orthographic projection of an anode connection via V of a pixel drive circuit in any even-numbered row and any odd-numbered column on the base substrate is not overlapped with an orthographic projection of a first electrode of a light emitting device in any even-numbered row and any odd-numbered column on the base substrate. For example, an orthographic projection of an anode connection via V in a second row and a first column on the base substrate is not overlapped with an orthographic projection of a first electrode of a light emitting device in the second row and the first column on the base substrate, an orthographic projection of an anode connection via V in the second row and a third column on the base substrate is not overlapped with an orthographic projection of a first electrode of a light emitting device in the second row and the third column on the base substrate, and so on.

In an exemplary implementation, as shown in FIG. 5, the first anode connection line CL1 is electrically connected with a pixel drive circuit in the c-th row and the (4a−3)-th column and a first electrode of a light emitting device in the c-th row and the (4a−1)-th column, respectively. For example, the first anode connection line CL1 is electrically connected with a pixel drive circuit in the second row and the first column and a first electrode of a light emitting device in the second row and the third column, respectively, the first anode connection line CL1 is electrically connected with a pixel drive circuit in the second row and the fifth column and a first electrode of a light emitting device in the second row and the seventh column, respectively, the first anode connection line CL1 is electrically connected with a pixel drive circuit in the second row and the ninth column and a first electrode of a light emitting device in the second row and the eleventh column, respectively, and so on.

In an exemplary implementation, as shown in FIG. 5, the second anode connection line CL2 is electrically connected with a pixel drive circuit in the c-th row and the (4a−1)-th column and a first electrode of a light emitting device in the c-th row and the (4a−3)-th column, respectively. For example, the second anode connection line CL2 is electrically connected with a pixel drive circuit in the second row and the third column and a first electrode of a light emitting device in the second row and the first column, respectively, the second anode connection line CL2 is electrically connected with a pixel drive circuit in the second row and the seventh column and a first electrode of a light emitting device in the second row and the fifth column, respectively, the second anode connection line CL2 is electrically connected with a pixel drive circuit in the second row and the eleventh column and a first electrode of a light emitting device in the second row and the ninth column, respectively, and so on.

In an exemplary implementation, an area of the first electrode of the first light emitting device located in the odd-numbered row is larger than an area of the first electrode of the first light emitting device located in the even-numbered row, and an area of the first electrode of the second light emitting device located in the odd-numbered row is larger than an area of the first electrode of the second light emitting device located in the even-numbered row.

In an exemplary implementation, the first electrode of the first light emitting device located in the odd-numbered row includes a first electrode body portion and a first electrode connection portion connected to a pixel drive circuit to which the first light emitting device is connected. The first electrode of the first light emitting device located in even-numbered row includes the first electrode body portion, only.

In an exemplary implementation, the first electrode of the second light emitting device located in the odd-numbered row includes a second electrode body portion and a second electrode connection portion connected to a pixel drive circuit to which the second light emitting device is connected. The first electrode of the second light emitting device located in even-numbered row includes the second electrode body portion, only.

In an exemplary implementation, the first electrode of the third light emitting device includes a third electrode body portion and a third electrode connection portion.

In an exemplary implementation, as shown in FIG. 6, the (4a−3)-th column pixel drive circuits belong to the second pixel drive circuit P2, and the (4a−1)-th column pixel drive circuits belong to the first pixel drive circuit P1. For example, the first column pixel drive circuit, the fifth column pixel drive circuit, the ninth column pixel drive circuit and the like belong to the second pixel drive circuit P2, and the second column pixel drive circuit, the fifth column pixel drive circuit, the ninth column pixel drive and the like belong to the first pixel drive circuit P1.

In an exemplary implementation, as shown in FIG. 6, an orthographic projection of an anode connection via V of a pixel drive circuit in a c-th row and a d-th column on the base substrate is partially overlapped with an orthographic projection of a first electrode of a light emitting device in the c-th row and the d-th column on the base substrate, wherein 1≤c≤N, and c is an even number, 1≤d≤M, and d is an odd number, and N is the total number of columns of the pixel drive circuits. That is, an orthographic projection of an anode connection via V of a pixel drive circuit in any even-numbered row and any odd-numbered column on the base substrate is partially overlapped with an orthographic projection of a first electrode of a light emitting device in any even-numbered row and any odd-numbered column on the base substrate. For example, an orthographic projection of an anode connection via V in a second row and a first column on the base substrate is partially overlapped with an orthographic projection of a first electrode of a light emitting device in the second row and the first column on the base substrate, an orthographic projection of an anode connection via V in the second row and a third column on the base substrate is partially overlapped with an orthographic projection of a first electrode of a light emitting device in the second row and the third column on the base substrate, and so on.

In an exemplary implementation, as shown in FIG. 6, an orthographic projection of an anode connection via V of a pixel drive circuit in a b-th row and the d-th column on the base substrate is not overlapped with an orthographic projection of a first electrode of a light emitting device in the b-th row and the d-th column on the base substrate, wherein 1≤b≤N, and b is an even number. That is, an orthographic projection of an anode connection via V of a pixel drive circuit in any odd-numbered row and any odd-numbered column on the base substrate is not overlapped with an orthographic projection of a first electrode of a light emitting device in any odd-numbered row and any odd-numbered column on the base substrate. For example, an orthographic projection of an anode connection via V in a first row and a first column on the base substrate is not overlapped with an orthographic projection of a first electrode of a light emitting device in the first row and the first column on the base substrate, an orthographic projection of an anode connection via V in the first row and a third column on the base substrate is not overlapped with an orthographic projection of a first electrode of a light emitting device in the first row and the third column on the base substrate, and so on.

In an exemplary implementation, as shown in FIG. 6, the first anode connection line CL1 is electrically connected with a pixel drive circuit in the b-th row and the (4a−1)-th column and a first electrode of a light emitting device in the b-th row and the (4a−3)-th column, respectively. For example, the first anode connection line CL1 is electrically connected with a pixel drive circuit in the first row and the third column and a first electrode of a light emitting device in the first row and the first column, respectively, the first anode connection line CL1 is electrically connected with a pixel drive circuit in the first row and the seventh column and a first electrode of a light emitting device in the first row and the ninth column, respectively, the first anode connection line CL1 is electrically connected with a pixel drive circuit in the second row and the eleventh column and a first electrode of a light emitting device in the second row and the ninth column, respectively, and so on.

In an exemplary implementation, as shown in FIG. 6, the second anode connection line CL2 is electrically connected with a pixel drive circuit in the b-th row and the (4a−3)-th column and a first electrode of a light emitting device in the b-th row and the (4a−1)-th column, respectively. For example, the second anode connection line CL2 is electrically connected with a pixel drive circuit in the first row and the first column and a first electrode of a light emitting device in the first row and the third column, respectively, the second anode connection line CL2 is electrically connected with a pixel drive circuit in the first row and the fifth column and a first electrode of a light emitting device in the second row and the seventh column, respectively, the second anode connection line CL2 is electrically connected with a pixel drive circuit in the first row and the ninth column and a first electrode of a light emitting device in the second row and the eleventh column, respectively, and so on.

In an exemplary implementation, an area of the first electrode of the first light emitting device located in the even-numbered row is larger than an area of the first electrode of the first light emitting device located in the odd-numbered row, and an area of the first electrode of the second light emitting device located in the even-numbered row is larger than an area of the first electrode of the second light emitting device located in the odd-numbered row.

In an exemplary implementation, the first electrode of the first light emitting device located in the even-numbered row includes a first electrode body portion and a first electrode connection portion connected to a pixel drive circuit to which the first light emitting device is connected. The first electrode of the first light emitting device located in odd-numbered row includes the first electrode body portion, only.

In an exemplary implementation, the first electrode of the second light emitting device located in the even-numbered row includes a second electrode body portion and a second electrode connection portion connected to a pixel drive circuit to which the second light emitting device is connected. The first electrode of the second light emitting device located in odd-numbered row includes the second electrode body portion, only.

In an exemplary implementation, the first electrode of the third light emitting device includes a third electrode body portion and a third electrode connection portion.

In an exemplary implementation, when the (4a−3)-th column pixel drive circuits belong to the second pixel drive circuit P2, and the (4a−1)-th column pixel drive circuits belong to the first pixel drive circuit P1, or when the (4a−3)-th column pixel drive circuits belong to the first pixel drive circuit P1, and the (4a−1)-th column pixel drive circuits belong to the second pixel drive circuit P2, the first electrode of the first light emitting device may further include at least one first protrusion provided on the first electrode body portion. The first electrode of the second light emitting device may further include at least one second protrusion provided on the second electrode body portion. The first electrode of the third light emitting device may further include at least one third protrusion provided on the third electrode body portion.

In an exemplary implementation, the first protrusion, the second protrusion, and the third protrusion are configured to block light.

In an exemplary implementation, the orthographic projection of the first anode connection line on the base substrate is partially overlapped with orthographic projection of at least one of the first, second, and third protrusions on the base substrate.

In an exemplary implementation, the orthographic projection of the second anode connection line on the base substrate is partially overlapped with orthographic projection of at least one of the first, second, and third protrusions on the base substrate.

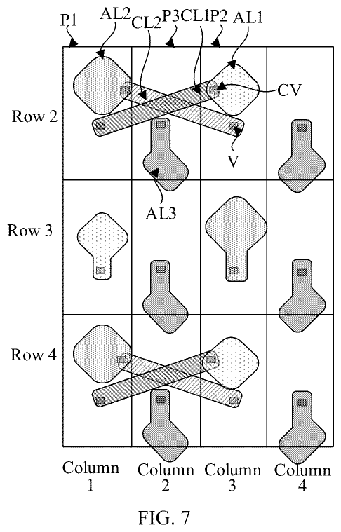

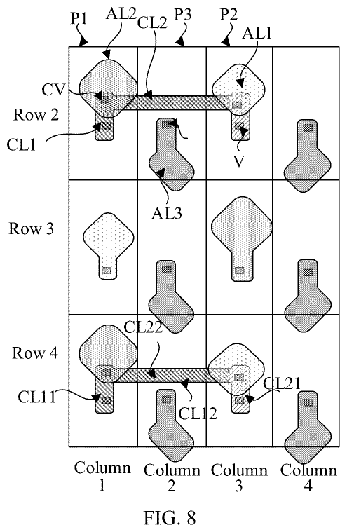

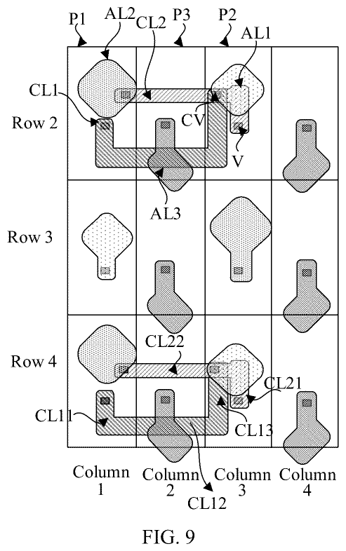

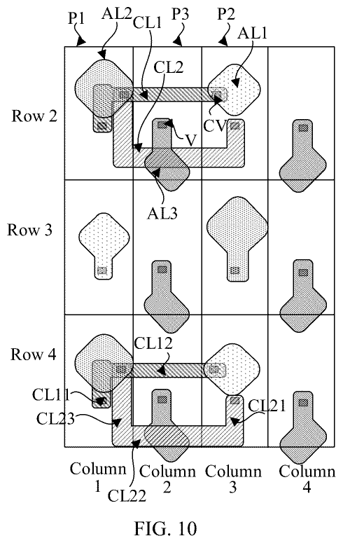

In an exemplary implementation, FIG. 7 is a first schematic cross-sectional view of a display substrate, FIG. 8 is a second schematic cross-sectional view of a display substrate, FIG. 9 is a third schematic cross-sectional view of a display substrate, and FIG. 10 is a fourth schematic cross-sectional view of a display substrate. As shown in FIGS. 7 to 10, the orthographic projection of the first anode connection line CL1 on the base substrate is at least partially overlapped with the orthographic projection of the second anode connection line CL2 on the base substrate. The orthographic projection of the first anode connection line CL1 on the base substrate and the orthographic projection of the second anode connection line CL2 on the base substrate, which are at least partially overlapped, can reduce lengths of the first anode connection line and the second anode connection line, reducing the cost of the display substrate. FIGS. 7 to 9 illustrate an example in which (4a−3)-th column first pixel drive circuits are taken as first pixel drive circuits, and (4a−1)-th column pixel drive circuits are taken as second pixel drive circuits. In FIGS. 7 to 10, CV refers to a transfer hole exposing the first anode connection line or the second anode connection line.

In an exemplary implementation, as shown in FIG. 7, the first anode connection line CL1 and the second anode connection line CL2 are linear, an extending direction of the first anode connection line CL1 intersects with an extending direction of the second anode connection line CL2, and both of the extending direction of the first anode connection line CL1 and the extending direction of the second anode connection line CL2 are different from the row direction and the column direction.

In an exemplary implementation, as shown in FIG. 7, the orthographic projection of the first anode connection line CL1 on the base substrate is not overlapped with the orthographic projections of the first electrode AL2 of the second light emitting device and the first electrode AL3 of the third light emitting device on the base substrate, the orthographic projection of the second anode connection line CL2 on the base substrate is not overlapped with the orthographic projections of the first electrode AL1 of the first light emitting device and the first electrode AL3 of the third light emitting device on the base substrate, and the first anode connection line CL1 and the second anode connection line CL2 are located on a same side of the anode connection via of the third pixel drive circuit.

In an exemplary implementation, as shown in FIG. 8, each of the first anode connection line CL1 and the second anode connection line CL2 includes a first connection segment and a second connection segment, wherein a first connection segment and a second connection segment located in a same anode connection line are connected and disposed at a right angle, the first connection segment extends in the column direction, and the second connection segment extends in the row direction.

In an exemplary implementation, as shown in FIG. 8, an orthographic projection of the first connection segment CL11 of the first anode connection line CL1 on the base substrate is partially overlapped with the orthographic projections of the anode connection via V of the first pixel drive circuit P1 and the first electrode AL2 of the second light emitting device on the base substrate, and an orthographic projection of the second connection segment CL12 of the first anode connection line CL1 on the base substrate is partially overlapped with orthographic projections of the second connection segment CL22 of the second anode connection line CL2, the first electrode AL1 of the first light emitting device and the first electrode AL2 of the second light emitting device on the base substrate.

In an exemplary implementation, as shown in FIG. 8, an orthographic projection of the first connection segment CL21 of the second anode connection line CL2 on the base substrate is partially overlapped with the orthographic projections of the anode connection via V of the second pixel drive circuit and the first electrode AL1 of the first light emitting device on the base substrate, and an orthographic projection of the second connection segment CL22 of the second anode connection line CL2 on the base substrate is partially overlapped with the orthographic projections of the first electrode AL1 of the first light emitting device and the first electrode AL2 of the second light emitting device on the base substrate.

In an exemplary implementation, as shown in FIG. 8, the orthographic projections of the first anode connection line CL1 and the second anode connection line CL2 on the base substrate are not overlapped with the orthographic projection of the first electrode AL3 of the third light emitting device on the base substrate, and are located on a same side of the anode connection via V of the third pixel drive circuit P3.

In an exemplary implementation, as shown in FIG. 9, the first anode connection line CL1 includes a first connection segment CL11, a second connection segment CL12 and a third connection segment CL13, wherein the first connection segment CL11 and the third connection segment CL13 extend along the column direction, and the second connection segment CL12 extends along the row direction. Both the first connection segment CL11 and the third connection segment CL13 are located on a same side of the second connection segment CL12, and are electrically connected with the second connection segment CL12, respectively. The second anode connection line CL2 includes a fourth connection segment CL21 and a fifth connection segment CL22 that are connected to each other and disposed at a right angle, wherein the fourth connection segment CL21 extends along the column direction, and the fifth connection segment CL22 extends along the row direction.

In an exemplary implementation, as shown in FIG. 9, an orthographic projection of the first connection segment CL11 of the first anode connection line CL1 on the base substrate is partially overlapped with an orthographic projection of an anode connection via V of the first pixel drive circuit on the base substrate, an orthographic projection of the second connection segment CL12 of the first anode connection line CL1 on the base substrate is partially overlapped with an orthographic projection of the first electrode AL3 of the third light emitting device on the base substrate, an orthographic projection of the third connection segment CL13 of the first anode connection line CL1 on the base substrate is partially overlapped with orthographic projections of the first electrode AL1 of the first light emitting device and the fifth connection segment CL22 of the second anode connection line CL2 on the base substrate, an orthographic projection of the fourth connection segment CL21 of the second anode connection line CL2 on the base substrate is partially overlapped with the orthographic projections of the anode connection via V of the second pixel drive circuit and the first electrode AL1 of the first light emitting device on the base substrate, and an orthographic projection of the fifth connection segment CL22 of the second anode connection line CL2 on the base substrate is partially overlapped with the first electrode AL1 of the first light emitting device and the first electrode AL2 of the second light emitting device.

In an exemplary implementation, as shown in FIG. 9, an orthographic projection of the second anode connection line CL2 on the base substrate is not overlapped with the orthographic projection of the first electrode AL3 of the third light emitting device on the base substrate, and the first anode connection line CL1 and the second anode connection line CL2 are located on different sides of an anode connection via V of the third pixel drive circuit.

In an exemplary implementation, as shown in FIG. 10, the second anode connection line CL2 includes a first connection segment CL21, a second connection segment CL22 and a third connection segment CL23, wherein the first connection segment CL21 and the third connection segment CL23 extend along the column direction, and the second connection segment CL22 extends along the row direction. Both the first connection segment CL21 and the third connection segment CL23 are located on a same side of the second connection segment CL22, and are electrically connected with the second connection segment CL22, respectively. The first anode connection line CL1 includes a fourth connection segment CL11 and a fifth connection segment CL12 that are connected to each other and disposed at a right angle, wherein the fourth connection segment CL11 extends along the column direction, and the fifth connection segment CL12 extends along the row direction.

In an exemplary implementation, as shown in FIG. 10, an orthographic projection of the fourth connection segment CL11 of the first anode connection line CL1 on the base substrate is partially overlapped with the orthographic projections of the anode connection via V of the first pixel drive circuit and the first electrode AL2 of the second light emitting device on the base substrate, and an orthographic projection of the fifth connection segment CL12 of the first anode connection line CL1 on the base substrate is partially overlapped with orthographic projections of the first electrode AL1 of the first light emitting device, the first electrode AL2 of the second light emitting device and the third connection segment CL23 of the second anode connection line CL2 on the base substrate.

In an exemplary implementation, as shown in FIG. 10, an orthographic projection of the first connection segment CL21 of the second anode connection line CL2 on the base substrate is partially overlapped with an orthographic projection of an anode connection via V of a second pixel drive circuit on the base substrate, an orthographic projection of the second connection segment CL22 of the second anode connection line CL2 on the base substrate is partially overlapped with an orthographic projection of a first electrode AL3 of the third light emitting device on the base substrate, and the orthographic projection of the third connection segment CL23 of the second anode connection line CL2 on the base substrate is partially overlapped with the orthographic projection of the first electrode AL2 of the second light emitting device on the base substrate.

In an exemplary implementation, as shown in FIG. 10, an orthographic projection of the first anode connection line CL1 on the base substrate is not overlapped with the orthographic projection of the first electrode AL3 of the third light emitting device on the base substrate, and the first anode connection line CL1 and the second anode connection line CL2 are located on different sides of an anode connection via V of the third pixel drive circuit.

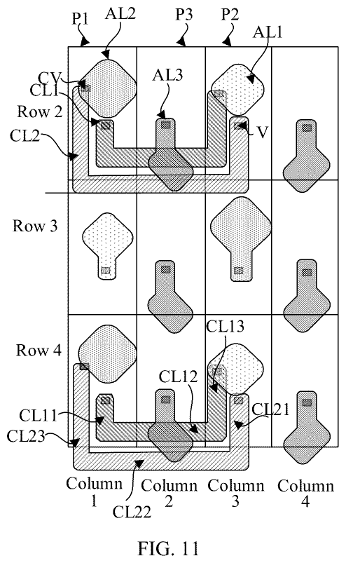

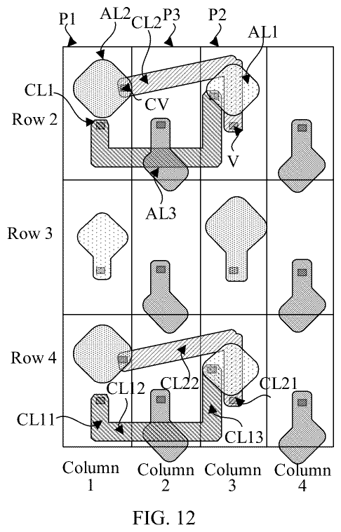

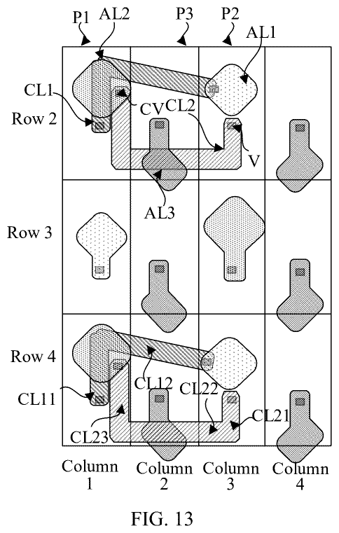

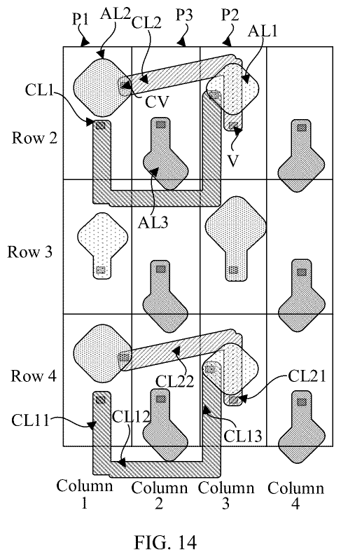

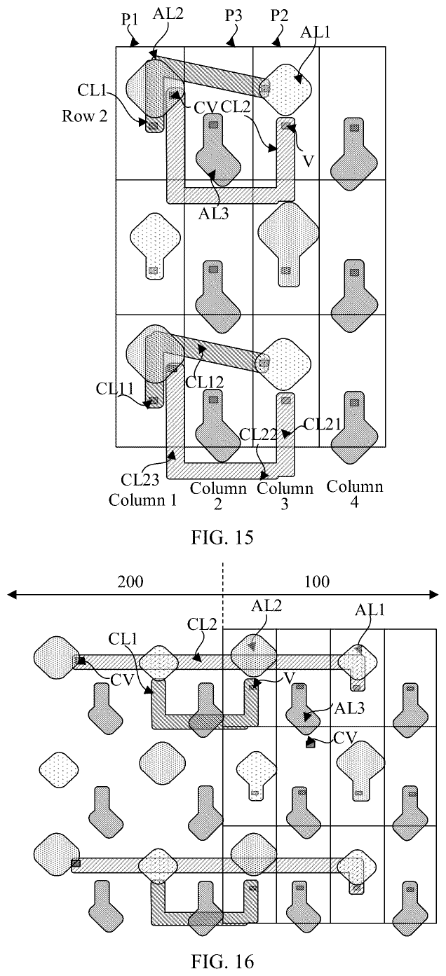

In an exemplary implementation, FIG. 11 is a fifth schematic cross-sectional view of a display substrate, FIG. 12 is a sixth schematic cross-sectional view of a display substrate, FIG. 13 is a seventh schematic cross-sectional view of a display substrate, FIG. 14 is an eighth schematic cross-sectional view of a display substrate, and FIG. 15 is a ninth schematic cross-sectional view of a display substrate. As shown in FIGS. 11 to 15, an orthographic projection of a first anode connection line CL1 on the base substrate is not overlapped with an orthographic projection of a second anode connection line CL2 on the base substrate. The non-overlap of the orthographic projection of the first anode connection line CL1 on the base substrate and the orthographic projection of the second anode connection line CL2 on the base substrate may reduce crosstalk between signals of the first anode connection line and the second anode connection line. FIGS. 11 to 15 illustrate an example in which (4a−3)-th column first pixel drive circuits are taken as first pixel drive circuits, and (4a−1)-th column pixel drive circuits are taken as second pixel drive circuits. In FIGS. 11 to 15, CV refers to a transfer hole exposing the first anode connection line or the second anode connection line.

In an exemplary implementation, as shown in FIG. 11, each of the first anode connection line CL1 and the second anode connection line CL2 includes a first connection segment, a second connection segment, and a third connection segment, wherein the first connection segment and the third connection segment extend along the column direction, the second connection segment extends along the row direction, the first connection segment and the third connection segment are located on a same side of the second connection segment, and are electrically connected with the second connection segment, respectively.

In an exemplary implementation, as shown in FIG. 11, an orthographic projection of the first connection segment of the first anode connection line CL1 on the base substrate is partially overlapped with an orthographic projection of an anode connection via V of a first pixel drive circuit on the base substrate, an orthographic projection of the second connection segment CL12 of the first anode connection line CL1 on the base substrate is partially overlapped with an orthographic projection of a first electrode AL3 of a third light emitting device on the base substrate, and an orthographic projection of the third connection segment CL13 of the first anode connection line CL1 on the base substrate is partially overlapped with an orthographic projection of a first electrode AL1 of a first light emitting device on the base substrate.

In an exemplary implementation, as shown in FIG. 11, an orthographic projection of the first connection segment CL21 of the second anode connection line CL2 on the base substrate is partially overlapped with an orthographic projection of an anode connection via V of the second pixel drive circuit on the base substrate, an orthographic projection of the second connection segment CL22 of the second anode connection line CL2 on the base substrate is partially overlapped with the orthographic projection of the first electrode AL3 of the third light emitting device on the base substrate, and an orthographic projection of the third connection segment CL23 of the second anode connection line CL2 on the base substrate is partially overlapped with an orthographic projection of a first electrode AL2 of a second light emitting device on the base substrate.

In an exemplary implementation, as shown in FIG. 11, the first anode connection line CL1 and the second anode connection line CL2 are located on a same side of the anode connection via V of a third pixel drive circuit, respectively.

In an exemplary implementation, as shown in FIGS. 12 and 14, the first anode connection line CL1 includes a first connection segment CL11, a second connection segment CL12 and a third connection segment CL13, wherein the first connection segment CL11 and the third connection segment CL13 extend along the column direction, and the second connection segment CL12 extends along the row direction. Both the first connection segment CL11 and the third connection segment CL13 are located on a same side of the second connection segment CL12, and are electrically connected with the second connection segment CL12, respectively. The second anode connection line CL2 includes a fourth connection segment CL21 and a fifth connection segment CL22 that are connected to each other and disposed at an acute angle, wherein the fourth connection segment CL21 extends along the column direction.

In an exemplary implementation, as shown in FIGS. 12 and 14, an orthographic projection of the first connection segment CL11 of the first anode connection line CL1 on the base substrate is partially overlapped with an orthographic projection of an anode connection via V of a first pixel drive circuit on the base substrate, an orthographic projection of the second connection segment CL12 of the first anode connection line CL1 on the base substrate is partially overlapped, or is not overlapped, with an orthographic projection of a first electrode AL3 of a third light emitting device on the base substrate, and an orthographic projection of the third connection segment CL13 of the first anode connection line CL1 on the base substrate is partially overlapped with an orthographic projection of a first electrode AL1 of a first light emitting device on the base substrate. FIG. 12 illustrates an example in which the orthographic projection of the second connection segment CL12 of the first anode connection line CL1 on the base substrate is partially overlapped with the orthographic projection of the first electrode AL3 of the third light emitting device on the base substrate, and FIG. 14 illustrates an example in which the orthographic projection of the second connection segment CL12 of the first anode connection line CL1 on the base substrate is not overlapped with the orthographic projection of the first electrode AL3 of the third light emitting device on the base substrate.

In an exemplary implementation, as shown in FIGS. 12 and 14, an orthographic projection of the fourth connection segment CL21 of the second anode connection line CL2 on the base substrate is partially overlapped with an orthographic projection of an anode connection via V of a second pixel drive circuit and the orthographic projection of the first electrode AL1 of the first light emitting device on the base substrate, and an orthographic projection of the fifth connection segment CL22 of the second anode connection line CL2 on the base substrate is partially overlapped with a first electrode AL2 of a second light emitting device.

In an exemplary implementation, as shown in FIGS. 12 and 14, an orthographic projection of the second anode connection line CL2 on the base substrate is not overlapped with the orthographic projection of the first electrode AL3 of the third light emitting device on the base substrate, and the first anode connection line CL1 and the second anode connection line CL2 are located on different sides of an anode connection via V of a third pixel drive circuit.

In an exemplary implementation, as shown in FIGS. 13 and 15, the second anode connection line CL2 includes a first connection segment CL21, a second connection segment CL22 and a third connection segment CL23, wherein the first connection segment CL21 and the third connection segment CL23 extend along the column direction, and the second connection segment CL22 extends along the row direction. Both the first connection segment CL21 and the third connection segment CL23 are located on a same side of the second connection segment CL22, and are electrically connected with the second connection segment CL22, respectively. The first anode connection line CL1 includes a fourth connection segment CL11 and a fifth connection segment CL12 that are connected to each other and disposed at an acute angle, wherein the fourth connection segment CL11 extends along the column direction.

In an exemplary implementation, as shown in FIGS. 13 and 15, an orthographic projection of the fourth connection segment CL11 of the first anode connection line CL1 on the base substrate is partially overlapped with orthographic projections of an anode connection via V of the first pixel drive circuit and a first electrode AL2 of a second light emitting device on the base substrate, and an orthographic projection of the fifth connection segment CL12 of the first anode connection line CL1 on the base substrate is partially overlapped with an orthographic projection of the first electrode AL1 of the first light emitting device on the base substrate.

In an exemplary implementation, as shown in FIGS. 13 and 15, an orthographic projection of the first connection segment CL21 of the second anode connection line CL2 on the base substrate is partially overlapped with an orthographic projection of an anode connection via V of the second pixel drive circuit on the base substrate, an orthographic projection of the second connection segment CL22 of the second anode connection line CL2 on the base substrate is partially overlapped, or is not overlapped, with an orthographic projection of a first electrode AL3 of a third light emitting device on the base substrate, and an orthographic projection of the third connection segment CL23 of the second anode connection line CL2 on the base substrate is partially overlapped with the orthographic projection of the first electrode AL2 of the second light emitting device on the base substrate.

In an exemplary implementation, as shown in FIGS. 13 and 15, an orthographic projection of the first anode connection line CL1 on the base substrate is not overlapped with the orthographic projection of the first electrode AL3 of the third light emitting device on the base substrate, and the first anode connection line CL1 and the second anode connection line CL2 are located on different sides of an anode connection via V of a third pixel drive circuit.

In an exemplary implementation, the light emitting device in FIGS. 7 to 15 may be located only in a first drive region, or at least in a first drive region.

In an exemplary implementation, the first drive region may include a first display region and a second display region, wherein the first display region at least partially surrounds the second display region, the second display region may be a light-transmitting display region, and the first display region may be a normal display region. At that time, the display substrate may be a display substrate provided with a Camera Under Panel (CUP).

In an exemplary implementation, FIG. 16 is a schematic cross-sectional view of another display substrate. As shown in FIG. 16, a based substrate further includes a second drive region 200, a first drive region 100 includes a first side and a second side disposed oppositely, and the second drive region 200 is located on at least one of the first side and the second side of the first drive region 100. The second drive region 200 is further provided with a gate drive circuit configured to provide a control signal to a pixel drive circuit, and a light emitting device. The light emitting device in the display substrate in FIG. 16 may be disposed on the pixel drive circuit and the gate drive circuit. In FIG. 16, CV refers to a transfer hole exposing the first anode connection line or the second anode connection line.

In an exemplary implementation, as shown in FIG. 16, at least one first anode connection line CL1 is electrically connected with a first pixel drive circuit located in the first drive region and a first electrode AL1 of at least one first light emitting device located in the second drive region, respectively, and at least one second anode connection line CL2 is electrically connected with a second pixel drive circuit located in the first drive region and a first electrode AL2 of at least one second light emitting device located in the second drive region, respectively.

The pixel drive circuit in the display substrate in FIG. 16 may include a display pixel drive circuit and a virtual pixel drive circuit, and a pixel drive circuit electrically connected with the first electrode AL1 of the at least one first light emitting device located in the second drive region may act as the virtual pixel drive circuit.

In an exemplary implementation, when an orthographic projection of the first anode connection line CL1 on the base substrate is partially overlapped with an orthographic projection of the second anode connection line CL2 on the base substrate, the first anode connection line CL1 and the second anode connection line CL2 are disposed in different layers.

In an exemplary implementation, when the orthographic projection of the first anode connection line CL1 on the base substrate is not overlapped with the orthographic projection of the second anode connection line CL2 on the base substrate, the first anode connection line CL1 and the second anode connection line CL2 are disposed in different layers, or in a same layer.

In an exemplary implementation, the first anode connection line CL1 may include a metal line or a transparent conductive line.

In an exemplary implementation, the second anode connection line CL2 may include a metal line or a transparent conductive layer.

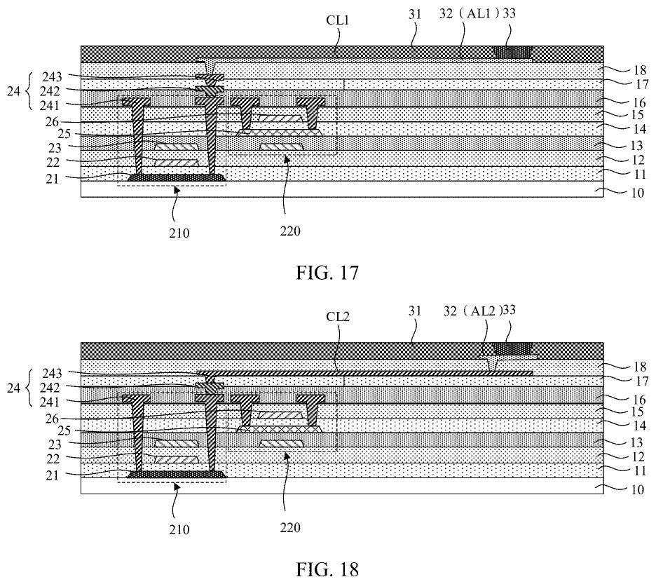

In an exemplary implementation, FIG. 17 is a schematic cross-sectional view along an A-A direction in FIG. 7, and FIG. 18 is a schematic cross-sectional view along a B-B direction in FIG. 7. As shown in FIGS. 17 and 18, the display substrate includes a driving structure layer and a light emitting structure layer which are provided on the base substrate 10, wherein the driving structure layer is provided with a pixel drive circuit, a gate drive circuit and a data signal line, and the light emitting structure layer is provided with a light emitting device. The pixel drive circuit includes a transistor and a capacitor, wherein the capacitor includes a first plate and a second plate.

In an exemplary implementation, the driving structure layer includes a first conductive layer 22, a second conductive layer 23, and a third conductive layer 24 sequentially stacked on the base substrate 10, and the light emitting structure layer includes a fourth conductive layer 32, an organic light emitting layer 33, and a fifth conductive layer.

In an exemplary implementation, the first conductive layer 22 may include, at least, gate electrodes of a plurality of transistors, the first plate of the capacitor, and a gate line. When the pixel drive circuit is shown in FIG. 3A, the gate line includes a scan signal line, a reset signal line, and a light emitting signal line. When the pixel drive circuit is shown in FIG. 4A, the gate line includes a scan signal line, a reset signal line, a light emitting signal line, and a control signal line.

In an exemplary implementation, the second conductive layer 23 may include, at least, the second plate of the capacitor.

In an exemplary implementation, the third conductive layer 24 includes, at least, source and drain electrodes of a plurality of transistors and a data signal line.

In an exemplary implementation, the fourth conductive layer 32 includes, at least, a first electrode of the light emitting device. FIG. 17 illustrates an example in which the light emitting device is a first light emitting device, and FIG. 18 illustrates an example in which the light emitting device is a second light emitting device.

In an exemplary implementation, the light emitting structure layer may further include a pixel definition layer 31.

In an exemplary implementation, the first anode connection line CL1 is located in the third conductive layer or the fourth conductive layer. FIG. 17 illustrates an example in which the first anode connection line CL1 is located in the fourth conductive layer.

In an exemplary implementation, the second anode connection line CL2 is located in the third conductive layer or the fourth conductive layer. FIG. 18 illustrates an example in which the second anode connection line CL2 is located in the third conductive layer.

In an exemplary implementation, the third conductive layer may be in a single-layer structure or a multi-layer structure.

In an exemplary implementation, when the third conductive layer is in the multi-layer structure, the third conductive layer includes a first sub-conductive layer and a second sub-conductive layer, or the third conductive layer includes a first sub-conductive layer a second sub-conductive layer, and a third sub-conductive layer, wherein the first sub-conductive layer and the second sub-conductive layer are metal conductive layers, and the third sub-conductive layer includes a metal conductive layer or a transparent conductive layer. FIGS. 17 and 18 illustrate an example in which the third conductive layer 24 includes a first sub-conductive layer 241, a second sub-conductive layer 242, and a third sub-conductive layer 243, wherein the third sub-conductive layer is a metal conductive layer.

In an exemplary implementation, when the third sub-conductive layer is a transparent conductive layer, there is at least one third sub-conductive layer. For example, a quantity of the third sub-conductive layers may be one, or may be three. For example, the third conductive layer may include a first metal conductive layer and a second metal conductive layer disposed in a stack, or may include a first metal conductive layer, a second metal conductive layer, and a third metal conductive layer disposed in a stack, or may include a first metal conductive layer, a second metal conductive layer, and a transparent conductive layer disposed in a stack, or may include a first metal conductive layer, a second metal conductive layer, a first transparent conductive layer, a second transparent conductive layer and a third transparent conductive layer disposed in a stack.

In an exemplary implementation, when the display substrate is the display substrate in FIG. 16, the third sub-conductive layer may include one transparent conductive layer, and when the display substrate is a display substrate provided with a Camera Under Panel (CUP), the third sub-conductive layer may include three transparent conductive layers.

In an exemplary implementation, when the third conductive layer is in a multi-layer structure, the first anode connection line CL1 and the second anode connection line CL2 are located in at least one film of the third conductive layer. For example, when the third conductive layer includes a first metal conductive layer and a second metal conductive layer disposed in a stack, the first anode connection line CL1 may be located in one of the first metal conductive layer and the second metal conductive layer, and the second anode connection line CL2 may be located in one of the first metal conductive layer and the second metal conductive layer. When the third conductive layer includes a first metal conductive layer, a second metal conductive layer and a third metal conductive layer disposed in a stack, the first anode connection line CL1 may be located in one of the first metal conductive layer, the second metal conductive layer and the third metal conductive layer, and the second anode connection line CL2 may be located in one of the first metal conductive layer, the second metal conductive layer and the third metal conductive layer. When the third conductive layer includes a first metal conductive layer, a second metal conductive layer and a transparent conductive layer disposed in a stack, the first anode connection line CL1 may be located in one of the first metal conductive layer, the second metal conductive layer and the transparent conductive layer, and the second anode connection line CL2 may be located in one of the first metal conductive layer, the second metal conductive layer, and the transparent conductive layer. When the third conductive layer includes a first metal conductive layer, a second metal conductive layer, a first transparent conductive layer, a second transparent conductive layer and a third transparent conductive layer disposed in a stack, the first anode connection line CL1 may be located in one of the first metal conductive layer, the second metal conductive layer, the first transparent conductive layer, the second transparent conductive layer, and the third transparent conductive layer, and the second anode connection line CL2 may be located in one of the first metal conductive layer, the second metal conductive layer, the first transparent conductive layer, the second transparent conductive layer, and the third transparent conductive layer, which is not limited in the present disclosure.

In an exemplary implementation, the first anode connection line CL may be made of a manufacturing material line the same as the film disposed in the same layer, or may be made of a manufacturing material different from the film disposed in the same layer, which is not limited in the present disclosure.

In an exemplary implementation, the first conductive layer, the second conductive layer and the third conductive layer may be made of a metal material, such as any one or more of Argentum (Ag), Copper (Cu), Aluminum (Al) and Molybdenum (Mo), or an alloy material of the above-mentioned metals, such as, an Aluminum-Neodymium alloy (AlNd) or a Molybdenum-Niobium alloy (MoNb), and may be in a single-layer structure, or in a multi-layer composite structure such as Mo/Cu/Mo, Ti/Al/Ti, etc.

In an exemplary implementation, the fourth conductive layer is in a single-layer structure, such as Indium Tin Oxide (ITO) or Indium Zinc Oxide (IZO), or may be in a multi-layer composite structure, such as ITO/Ag/ITO.

In an exemplary implementation, the fifth conductive layer may be made of a metal material, such as any one or more of argentum (Ag), copper (Cu), aluminum (Al), and molybdenum (Mo), or a conductive alloy material of the above-mentioned metals, such as an Aluminum Neodymium alloy (AlNd) or a Molybdenum Niobium alloy (MoNb), and may be in a single-layer structure or a multi-layer composite structure, such as Mo/Cu/Mo. For example, the fourth conductive layer may be in a three-layer stacked structure formed of titanium, aluminum, and titanium.

In an exemplary implementation, the transistor in the pixel drive circuit includes a low-temperature polysilicon transistor, or may include a low-temperature polysilicon transistor and an oxide transistor. FIGS. 17 and 18 illustrate an example in which the pixel drive circuit includes a low-temperature polysilicon transistor 210 and an oxide transistor 220.

In an exemplary implementation, when the transistor in the pixel drive circuit includes a low-temperature polysilicon transistor, the driving structure layer may further include a semiconductor layer located on a side of the first conductive layer close to the base substrate.

In an exemplary implementation, a semiconductor layer pattern may be an amorphous silicon layer, a polysilicon layer, or may be a metal oxide layer. The metal oxide layer may be an oxide including indium and tin, an oxide including tungsten and indium, an oxide including tungsten, indium, and zinc, an oxide including titanium and indium, an oxide including titanium, indium, and tin, an oxide including indium and zinc, an oxide including silicon, indium, and tin, or an oxide including indium or gallium and zinc. The metal oxide layer may be mono-layered, double-layered or multi-layered.

In an exemplary implementation, the semiconductor layer may include, at least, an active layer of a transistor.

In an exemplary implementation, when the transistor in the pixel drive circuit includes a low-temperature polysilicon transistor, the driving structure layer may further include insulation layers located between the semiconductor layer, the first conductive layer, the second conductive layer and the third conductive layer, and a planarization layer located on a side of the third conductive layer away from the base substrate.

In an exemplary implementation, as shown in FIGS. 17 and 18, when the transistor in the pixel drive circuit includes a low-temperature polysilicon transistor and an oxide transistor, the driving structure layer may further include a first semiconductor layer 21 located on a side of the first conductive layer close to the base substrate, a second semiconductor layer 25 located on a side of the second conductive layer away from the base substrate, and a sixth conductive layer 26 located between the second semiconductor layer and the third conductive layer.

In an exemplary implementation, the first semiconductor layer may include, at least, an active layer of a low-temperature polysilicon transistor.

In an exemplary implementation, the second semiconductor layer may include, at least, an active layer of the oxide transistor.

In an exemplary implementation, a first semiconductor layer pattern may be an amorphous silicon layer or a polysilicon layer.

In an exemplary implementation, a second semiconductor layer pattern may be a metal oxide layer. The metal oxide layer may be an oxide including indium and tin, an oxide including tungsten and indium, an oxide including tungsten, indium, and zinc, an oxide including titanium and indium, an oxide including titanium, indium, and tin, an oxide including indium and zinc, an oxide including silicon, indium, and tin, or an oxide including indium or gallium and zinc. The metal oxide layer may be mono-layered, double-layered or multi-layered.

In an exemplary implementation, when the transistor in the pixel drive circuit includes a low-temperature polysilicon transistor and an oxide transistor, a gate line connected to a gate electrode of the oxide transistor is double-layered, and includes a first sub-gate line and a second sub-gate line.

In an exemplary implementation, the third conductive layer may include, at least, a first sub-gate line of a gate line connected to the gate electrode of the oxide transistor.

In an exemplary implementation, the sixth conductive layer may include, at least, a second sub-gate line of a gate line connected to the gate electrode of the oxide transistor.

In an exemplary implementation, the sixth conductive layer may be made of a metal material, such as any one or more of Argentum (Ag), Copper (Cu), Aluminum (Al), and Molybdenum (Mo), or an alloy material of the above-mentioned metals, such as an Aluminum-Neodymium alloy (AlNd) or a Molybdenum-Niobium alloy (MoNb), and may be in a single-layer structure, or in a multi-layer composite structure, such as Mo/Cu/Mo, Ti/Al/Ti, etc.

In an exemplary implementation, as shown in FIGS. 17 and 18, when the transistor in the pixel drive circuit includes a low-temperature polysilicon transistor and an oxide transistor, the driving structure layer may further include an insulation layer located between any two adjacent films of the first semiconductor layer, the first conductive layer, the second conductive layer, the second semiconductor layer, the sixth conductive layer, and the third conductive layer, and a planarization layer on a side of the third conductive layer close to the base substrate.

In an exemplary implementation, when the third conductive layer is in a multi-layer structure, a planarization layer is provided between adjacent films in the third conductive layer. For example, when the third conductive layer may include a first metal conductive layer and a second metal conductive layer disposed in a stack, a planarization layer is provided between the first metal conductive layer and the second metal conductive layer. When the third conductive layer includes a first metal conductive layer, a second metal conductive layer and a third metal conductive layer disposed in a stack, a planarization layer is provided between the first metal conductive layer and the second metal conductive layer, and a planarization layer is provided between the second metal conductive layer and the third metal conductive layer. When the third conductive layer includes a first metal conductive layer, a second metal conductive layer and a transparent conductive layer disposed in a stack, a planarization layer is provided between the first metal conductive layer and the second metal conductive layer, and a planarization layer is provided between the second metal conductive layer and the transparent conductive layer. When the third conductive layer includes a first metal conductive layer, a second metal conductive layer, a first transparent conductive layer, a second transparent conductive layer and a third transparent conductive layer disposed in a stack, a planarization layer is provided between the first metal conductive layer and the second metal conductive layer, a planarization layer is provided between the second metal conductive layer and the first transparent conductive layer, a planarization layer is provided between the first transparent conductive layer and the second transparent conductive layer, and a planarization layer is provided between the second transparent conductive layer and the third transparent conductive layer.

In an exemplary implementation, as shown in FIGS. 17 and 18, the driving structure layer may include a first insulation layer 11 located between the first semiconductor layer 21 and the first conductive layer 22, a second insulation layer 12 located between the first conductive layer 22 and the second conductive layer 23, a third insulation layer 13 located between the second conductive layer 23 and the second semiconductor layer 25, a sixth insulation layer 14 located between the second semiconductor layer and the sixth conductive layer 26, a fifth insulation layer 15 located between the sixth conductive layer 26 and the first sub-conductive layer 241, a first planarization layer 16 located between the first sub-conductive layer 241 and the second sub-conductive layer 242, a second planarization layer 17 located between the second sub-conductive layer 242 and the third sub-conductive layer 243, and a third planarization layer 18 disposed on a side of the third sub-conductive layer 243 away from the base substrate.

In an exemplary implementation, the insulation layer may be made of any one or more of silicon oxide (SiOx), silicon nitride (SiNx), and silicon oxynitride (SiON), and may be in a form of a single layer, multi-layer or composite layer.

In an exemplary implementation, the planarization layer may be made of an organic material, such as resin.

In an exemplary implementation, the display substrate further includes an encapsulation structure layer arranged on a side of the light emitting structure layer away from the base substrate.

In an exemplary implementation, the display substrate may further include another film, such as a touch control structure layer, which is not limited in the present disclosure.

The display substrate according to the embodiment of the present disclosure may be applied to a display product with any resolution.

A display apparatus is also provided in an embodiment of the present disclosure, including a display substrate.

The display substrate is the display substrate according to any of the aforementioned embodiments, and has similar implementation principles and implementation effects, which will not be repeated here.

In an exemplary implementation, the display substrate may be a flexible OLED display substrate, a QLED display substrate, a Micro-LED display substrate, or a Mini-LED display substrate. The display apparatus may be any product or component with a display function such as an OLED display, a cell phone, a tablet, a television, a display, a laptop, a digital photo frame, and a navigator, which is not limited in the embodiments of the present disclosure.

The accompanying drawings of the present disclosure only involve the structures involved in the embodiments of the present disclosure, and other structures may refer to usual designs.

For the sake of clarity, a thickness and size of a layer or a micro structure are enlarged in the accompanying drawings used for describing the embodiments of the present disclosure. It may be understood that when an element such as a layer, film, region, or substrate is described as being “on” or “under” another element, the element may be “directly” located “on” or “under” the another element, or there may be an intermediate element.

Although implementations of the present disclosure are disclosed above, contents described are only implementations used for ease of understanding of the present disclosure, but not intended to limit the present disclosure. Any of those skilled in the art of the present disclosure can make any modifications and variations in the implementation and details without departing from the spirit and scope of the present disclosure. However, the protection scope of the present disclosure should be subject to the scope defined by the appended claims.

1. A display substrate comprising: a based substrate, pixel drive circuits in a plurality of rows and columns, light emitting devices in a plurality of rows and columns, a plurality of data signal lines and a plurality of anode connection lines, which are disposed on the based substrate, wherein
the based substrate comprises a first drive region in which the pixel drive circuits and the data signal lines are located, and the light emitting devices and the anode connection lines are located, at least partially;
a pixel drive circuit is connected to a data signal line and a light emitting device, respectively, the light emitting device comprises a first light emitting device, a second light emitting device and a third light emitting device, a plurality of first light emitting devices and a plurality of second light emitting devices are alternately arranged in a column direction, and a plurality of third light emitting devices are arranged in the column direction, a light emitting device comprises a first electrode;
in the first drive region, a light emitting device in an n-th row and a (4a−3)-th column is a first light emitting device, a light emitting device in the n-th row and a (4a−1)-th column is a second light emitting device, a light emitting device in an (n+1)-th row and the (4a−3)-th column is a second light emitting device, a light emitting device in the (n+1)-th row and the (4a−1)-th column is a first light emitting device, and a light emitting device in an even-numbered column is a third light emitting device, wherein 1≤a≤M/4, 1≤n≤N−1, M is a total number of columns of light emitting devices or pixel drive circuits in the first drive region, and is an even number, N is a total number of rows of light emitting devices or pixel drive circuits in the first drive region;
a pixel drive circuit in one of the odd-numbered column and the even-numbered column is electrically connected with the first electrode of the first light emitting device or the second light emitting device through the anode connection line, and a pixel drive circuit in the other of the odd-numbered column and the even-numbered column is electrically connected with the first electrode of the third light emitting device; and
an orthographic projection of a first electrode of a light emitting device connected to a pixel drive circuit in the n-th row and a (2f−1)-th column on the based substrate is partially overlapped with an orthographic projection of a region where a pixel drive circuit in the n-th row and a (2f+1)-th column is located on the based substrate, an orthographic projection of a first electrode of a light emitting device connected to the pixel drive circuit in the n-th row and the (2f+1)-th column on the based substrate is partially overlapped with an orthographic projection of a region where a pixel drive circuit in the n-th row and a (2f−1)-th column is located on the based substrate, and an orthographic projection of a first electrode of a light emitting device connected to a pixel drive circuit in the n-th row and the even-numbered column on the based substrate is partially overlapped with an orthographic projection of a region where the pixel drive circuit in the n-th row and the even-numbered column is located on the based substrate, wherein 1≤f≤M/2, and fis an odd.

2. The display substrate of claim 1, wherein the pixel drive circuit is provided with an anode connection via through which the first electrode of the light emitting device is electrically connected with the pixel drive circuit, and the pixel drive circuit comprises a first pixel drive circuit configured to drive the first light emitting device to emit light, a second pixel drive circuit configured to drive the second light emitting device to emit light, and a third pixel drive circuit configured to drive the third light emitting device to emit light;
the odd-numbered column pixel drive circuit is the first pixel drive circuit or the second pixel drive circuit, and the even-numbered column pixel drive circuit is the third pixel drive circuit;
an orthographic projection of a first electrode of at least one first light emitting device on the based substrate is partially overlapped with an orthographic projection of an anode connection line to which the first light emitting device is connected on the based substrate;
the orthographic projection of the first electrode of the at least one first light emitting device on the based substrate is not overlapped with an orthographic projection of an anode connection via of the first pixel drive circuit to which the first light emitting device is connected on the based substrate;
an orthographic projection of a first electrode of at least one second light emitting device on the based substrate is partially overlapped with an orthographic projection of an anode connection line to which the second light emitting device is connected on the based substrate;
the orthographic projection of the first electrode of the at least one second light emitting device on the based substrate is not overlapped with an orthographic projection of an anode connection via of the second pixel drive circuit to which the second light emitting device is connected on the based substrate; and
an orthographic projection of a first electrode of the third light emitting device on the based substrate is partially overlapped with an orthographic projection of an anode connection via of the third pixel drive circuit to which the third light emitting device is connected on the based substrate.

3. The display substrate of claim 2, wherein
the anode connection line comprises a first anode connection line and a second anode connection line;
the first anode connection line is electrically connected with a part of the first pixel drive circuits, and with a first electrode of a first light emitting device to which the part of the first pixel drive circuits is connected, respectively;
an orthographic projection of the first anode connection line on the based substrate is partially overlapped with an orthographic projection of an anode connection via of the connected first pixel drive circuit on the based substrate, and is partially overlapped with an orthographic projection of the first electrode of the connected first light emitting device on the based substrate;
the second anode connection line is electrically connected with a part of the second pixel drive circuits, and with a first electrode of a second light emitting device to which the part of the second pixel drive circuits is connected, respectively; and
an orthographic projection of the second anode connection line on the based substrate is partially overlapped with an orthographic projection of an anode connection via of the connected second pixel drive circuit on the based substrate, and is partially overlapped with an orthographic projection of the first electrode of the connected second light emitting device on the based substrate.

4. The display substrate of claim 3, wherein the orthographic projection of the first anode connection line on the based substrate is at least partially overlapped with the orthographic projection of the second anode connection line on the based substrate.

5. The display substrate of claim 4, wherein the first anode connection line and the second anode connection line are linear, an extending direction of the first anode connection line intersects with an extending direction of the second anode connection line, and both the extending direction of the first anode connection line and the extending direction of the second anode connection line are different from a row direction and a column direction; and
the orthographic projection of the first anode connection line on the based substrate is not overlapped with the orthographic projections of the first electrode of the second light emitting device and the first electrode of the third light emitting device on the based substrate, the orthographic projection of the second anode connection line on the based substrate is not overlap with the orthographic projections of the first electrode of the first light emitting device and the first electrode of the third light emitting device on the based substrate, and the first anode connection line and the second anode connection line are located on a same side of the anode connection via of the third pixel drive circuit.

6. The display substrate of claim 4, wherein
the first anode connection line and the second anode connection line comprise a first connection segment and a second connection segment, a first connection segment and a second connection segment located in a same anode connection line are connected and disposed at a right angle, the first connection segment extends along a column direction, and the second connection segment extends along a row direction;
an orthographic projection of the first connection segment of the first anode connection line on the based substrate is partially overlapped with the orthographic projections of the anode connection via of the first pixel drive circuit and the first electrode of the second light emitting device on the based substrate, an orthographic projection of the second connection segment of the first anode connection line on the based substrate is partially overlapped with an orthographic projection of the second connection segment of the second anode connection line on the based substrate, and the orthographic projections of the first electrode of the first light emitting device and the first electrode of the second light emitting device on the based substrate;
an orthographic projection of the first connection segment of the second anode connection line on the based substrate is partially overlapped with the orthographic projections of the anode connection via of the second pixel drive circuit and the first electrode of the first light emitting device on the based substrate, the orthographic projection of the second connection segment of the second anode connection line on the based substrate is partially overlapped with the orthographic projections of the first electrode of the first light emitting device and the first electrode of the second light emitting device on the based substrate; and
the orthographic projections of the first anode connection line and the second anode connection line on the based substrate are not overlapped with the orthographic projection of the first electrode of the third light emitting device on the based substrate, and are located on a same side of the anode connection via of the third pixel drive circuit.

7. The display substrate of claim 4, wherein
the first anode connection line comprises a first connection segment, a second connection segment and a third connection segment, the first connection segment and the third connection segment extend along a column direction, the second connection segment extends along a row direction, the first connection segment and the third connection segment are located on a same side of the second connection segment and electrically connected with the second connection segment, respectively;
the second anode connection line comprises a fourth connection segment and a fifth connection segment connected with each other and disposed at a right angle, the fourth connection segment extends along the column direction and the fifth connection segment extends along the row direction;
an orthographic projection of the first connection segment of the first anode connection line on the based substrate is partially overlapped with the orthographic projection of the anode connection via of the first pixel drive circuit on the based substrate, an orthographic projection of the second connection segment of the first anode connection line on the based substrate is partially overlapped with an orthographic projection of the first electrode of the third light emitting device on the based substrate, an orthographic projection of the third connection segment of the first anode connection line on the based substrate is partially overlapped with orthographic projections of the first electrode of the first light emitting device and the fifth connection segment of the second anode connection line on the based substrate, an orthographic projection of the fourth connection segment of the second anode connection line on the based substrate is partially overlapped with the orthographic projections of the anode connection via of the second pixel drive circuit and the first electrode of the first light emitting device on the based substrate, and an orthographic projection of the fifth connection segment of the second anode connection line on the based substrate is partially overlapped with the first electrode of the first light emitting device and the first electrode of the second light emitting device;
the orthographic projection of the second anode connection line on the based substrate is not overlapped with the orthographic projection of the first electrode of the third light emitting device on the based substrate, and the first anode connection line and the second anode connection line are located on different sides of the anode connection via of the third pixel drive circuit.

8. The display substrate of claim 4, wherein
the second anode connection line comprises a first connection segment, a second connection segment and a third connection segment, the first connection segment and the third connection segment extend along a column direction, the second connection segment extends along a row direction, and the first connection segment and the third connection segment are located on a same side of the second connection segment and electrically connected with the second connection segment, respectively;
the first anode connection line comprises a fourth connection segment and a fifth connection segment connected with each other and disposed at a right angle, the fourth connection segment extends along the column direction and the fifth connection segment extends along the row direction;
an orthographic projection of the fourth connection segment of the first anode connection line on the based substrate is partially overlapped with the orthographic projections of the anode connection via of the first pixel drive circuit and the first electrode of the second light emitting device on the based substrate;
an orthographic projection of the fifth connection segment of the first anode connection line on the based substrate is partially overlapped with the orthographic projections of the first electrode of the first light emitting device, the first electrode of the second light emitting device and the third connection segment of the second anode connection line on the based substrate;
an orthographic projection of the first connection segment of the second anode connection line on the based substrate is partially overlapped with the orthographic projection of the anode connection via of the second pixel drive circuit on the based substrate;
an orthographic projection of the second connection segment of the second anode connection line on the based substrate is partially overlapped with the orthographic projection of the first electrode of the third light emitting device on the based substrate;
an orthographic projection of the third connection segment of the second anode connection line on the based substrate is partially overlapped with the orthographic projection of the first electrode of the second light emitting device on the based substrate;
the orthographic projection of the first anode connection line on the based substrate is not overlapped with the orthographic projection of the first electrode of the third light emitting device on the based substrate, and the first anode connection line and the second anode connection line are located on different sides of the anode connection via of the third pixel drive circuit.

9. The display substrate of claim 8, wherein the orthographic projection of the first anode connection line on the based substrate is not overlapped with the orthographic projection of the second anode connection line on the based substrate.

10. The display substrate of claim 9, wherein
each of the first anode connection line and the second anode connection line comprises a first connection segment, a second connection segment, and a third connection segment, the first connection segment and the third connection segment extend along the column direction, the second connection segment extends along the row direction, the first connection segment and the third connection segment are located on a same side of the second connection segment and electrically connected with the second connection segment, respectively;
an orthographic projection of the first connection segment of the first anode connection line on the based substrate is partially overlapped with the orthographic projection of the anode connection via of the first pixel drive circuit on the based substrate, an orthographic projection of the second connection segment of the first anode connection line on the based substrate is partially overlapped with the orthographic projection of the first electrode of the third light emitting device on the based substrate, an orthographic projection of the third connection segment of the first anode connection line on the based substrate is partially overlapped with the orthographic projection of the first electrode of the first light emitting device on the based substrate, an orthographic projection of the first electrode of the second light emitting device on the based substrate is partially overlapped with the orthographic projection of the anode connection via of the second pixel drive circuit on the based substrate, an orthographic projection of the second connection segment of the second anode connection line on the based substrate is partially overlapped with the orthographic projection of the first electrode of the third light emitting device on the based substrate, an orthographic projection of the third connection segment of the second anode connection line on the based substrate is partially overlapped with the orthographic projection of the first electrode of the second light emitting device on the based substrate; and
the first anode connection line and the second anode connection line are located on a same side of the anode connection via of the third pixel drive circuit.

11. The display substrate of claim 9, wherein
the first anode connection line comprises a first connection segment, a second connection segment and a third connection segment, the first connection segment and the third connection segment extend along a column direction, the second connection segment extends along a row direction, the first connection segment and the third connection segment are located on a same side of the second connection segment and electrically connected with the second connection segment, respectively;
the second anode connection line comprises a fourth connection segment and a fifth connection segment connected with each other and disposed at an acute angle, the fourth connection segment extends along the column direction;
an orthographic projection of the first connection segment of the first anode connection line on the based substrate is partially overlapped with the orthographic projection of the anode connection via of the first pixel drive circuit on the based substrate, an orthographic projection of the second connection segment of the first anode connection line on the based substrate is partially overlapped, or is not overlapped, with an orthographic projection of the first electrode of the third light emitting device on the based substrate, an orthographic projection of the third connection segment of the first anode connection line on the based substrate is partially overlapped with the orthographic projection of the first electrode of the first light emitting device on the based substrate, an orthographic projection of the fourth connection segment of the second anode connection line on the based substrate is partially overlapped with the orthographic projections of the anode connection via of the second pixel drive circuit and the first electrode of the first light emitting device on the based substrate, and an orthographic projection of the fifth connection segment of the second anode connection line on the based substrate is partially overlapped with the first electrode of the second light emitting device; and
the orthographic projection of the second anode connection line on the based substrate is not overlapped with the orthographic projection of the first electrode of the third light emitting device on the based substrate, and the first anode connection line and the second anode connection line are located on different sides of the anode connection via of the third pixel drive circuit.

12. The display substrate of claim 9, wherein
the second anode connection line comprises a first connection segment, a second connection segment and a third connection segment, the first connection segment and the third connection segment extend along a column direction, the second connection segment extends along a row direction, the first connection segment and the third connection segment are located on a same side of the second connection segment and electrically connected with the second connection segment, respectively;
the first anode connection line comprises a fourth connection segment and a fifth connection segment connected with each other and disposed at an acute angle, the fourth connection segment extends along the column direction;
an orthographic projection of the fourth connection segment of the first anode connection line on the based substrate is partially overlapped with the orthographic projections of the anode connection via of the first pixel drive circuit and the first electrode of the second light emitting device on the based substrate, an orthographic projection of the fifth connection segment of the first anode connection line on the based substrate is partially overlapped with the orthographic projection of the first electrode of the first light emitting device on the based substrate;
an orthographic projection of the first connection segment of the second anode connection line on the based substrate is partially overlapped with the orthographic projection of the anode connection via of the second pixel drive circuit on the based substrate, an orthographic projection of the second connection segment of the second anode connection line on the based substrate is partially overlapped, or is not overlapped, with the orthographic projection of the first electrode of the third light emitting device on the based substrate;
an orthographic projection of the third connection segment of the second anode connection line on the based substrate is partially overlapped with the orthographic projection of the first electrode of the second light emitting device on the based substrate; and
the orthographic projection of the first anode connection line on the based substrate is not overlapped with the orthographic projection of the first electrode of the third light emitting device on the based substrate, and the first anode connection line and the second anode connection line are located on different sides of the anode connection via of the third pixel drive circuit.

13. The display substrate of claim 3, wherein
a pixel drive circuit in the (4a−3)-th column is the first pixel drive circuit, and a pixel drive circuit in the (4a−1)-th column pixel drive circuit is the second pixel drive circuit;
an orthographic projection of an anode connection via of a pixel drive circuit in a b-th row and a d-th column on the based substrate is partially overlapped with an orthographic projection of a first electrode of a light emitting device in the b-th row and the d-th column on the based substrate;
an orthographic projection of an anode connection via of a pixel drive circuit in a c-th row and the d-th column on the based substrate is not overlapped with an orthographic projection of a first electrode of a light emitting device in the c-th row and the d-th column on the based substrate;
the first anode connection line is electrically connected with a pixel drive circuit in the c-th row and the (4a−3)-th column and a first electrode in the c-th row and the (4a−1)-th column, respectively; and
the second anode connection line is electrically connected with a pixel drive circuit in the c-th row and the (4a−1)-th column and a first electrode in the c-th row and the (4a−3)-th column, respectively; wherein 1≤b≤N, and b is an odd number; 1≤c≤N, and c is an even number; 1≤d≤M, and d is an odd number.

14. The display substrate of claim 13, wherein an area of the first electrode of the first light emitting device located in the odd-numbered row is larger than an area of the first electrode of the first light emitting device located in the even-numbered row, and an area of the first electrode of the second light emitting device located in the odd-numbered row is larger than an area of the first electrode of the second light emitting device located in the even-numbered row.

15. The display substrate of claim 3, wherein
a pixel drive circuit in the (4a−3)-th column is the second first pixel drive circuit, and a pixel drive circuit in the (4a−1)-th column pixel drive circuit is the first pixel drive circuit; an orthographic projection of an anode connection via of a pixel drive circuit in a c-th row and a d-th column on the based substrate is partially overlapped with an orthographic projection of a first electrode of a light emitting device in the c-th row and the d-th column on the based substrate;
an orthographic projection of an anode connection via of a pixel drive circuit in a b-th row and the d-th column on the based substrate is not overlapped with an orthographic projection of a first electrode of a light emitting device in the b-th row and the d-th column on the based substrate;
the first anode connection line is electrically connected with a pixel drive circuit in the b-th row and the (4a−1)-th column and a first electrode in the b-th row and the (4a−3)-th column, respectively; and
the second anode connection line is electrically connected with a pixel drive circuit in the b-th row and the (4a−3)-th column and a first electrode in the b-th row and the (4a−1)-th column, respectively; wherein 1≤b≤N, and b is an odd number; 1≤c≤N, and c is an even number; 1≤d≤M, and d is an odd number.

16. The display substrate of claim 15, wherein an area of the first electrode of the first light emitting device located in the even-numbered row is larger than an area of the first electrode of the first light emitting device located in the odd-numbered row, and an area of the first electrode of the second light emitting device located in the even-numbered row is larger than an area of the first electrode of the second light emitting device located in the odd-numbered row.

17. The display substrate of claim 14, wherein
the based substrate further comprises a second drive region, the first drive region comprises a first side and a second side disposed oppositely, the second drive region is located on at least one of the first side and the second side of the first drive region, the second drive region is further provided with a gate drive circuit and a light emitting device, and the gate drive circuit is configured to provide a control signal to a pixel drive circuit;
at least one first anode connection line is electrically connected with a first pixel drive circuit located in the first drive region and a first electrode of at least one first light emitting device located in the second drive region, respectively; and
at least one second anode connection line is electrically connected with a second pixel drive circuit located in the first drive region and a first electrode of at least one second light emitting device located in the second drive region, respectively.

18. The display substrate of claim 17, wherein
when the orthographic projection of the first anode connection line on the based substrate is partially overlapped with the orthographic projection of the second anode connection line on the based substrate, the first anode connection line and the second anode connection line are disposed in different layers;
when the orthographic projection of the first anode connection line on the based substrate is not overlapped with the orthographic projection of the second anode connection line on the based substrate, the first anode connection line and the second anode connection line are disposed in different layers or in a same layer; and
the first anode connection line comprises a metal line or a transparent conductive line, and the second anode connection line comprises a metal line or a transparent conductive layer.

19. The display substrate of claim 18, wherein
the display substrate comprises a driving structure layer and a light emitting structure layer which are provided on the based substrate, the driving structure layer is provided with a pixel drive circuit, a gate drive circuit and a data signal line, and the light emitting structure layer is provided with a light emitting device;
the driving structure layer comprises a first conductive layer, a second conductive layer and a third conductive layer sequentially stacked on the based substrate, and the light emitting structure layer comprises a fourth conductive layer, an organic light emitting layer and a fifth conductive layer;
the third conductive layer comprises, at least, source and drain electrodes of a plurality of transistors and a data signal line;
the fourth conductive layer comprises, at least, a first electrode of the light emitting device;
the first anode connection line is located in the third conductive layer or the fourth conductive layer, and the second anode connection line is located in the third conductive layer or the fourth conductive layer;
the third conductive layer is in a single-layer structure or a multi-layer structure;
when the third conductive layer is in the multi-layer structure, the third conductive layer comprises a first sub-conductive layer and a second sub-conductive layer, or the third conductive layer comprises a first sub-conductive layer, a second sub-conductive layer and a third sub-conductive layer, wherein the first sub-conductive layer and the second sub-conductive layer are metal conductive layers, and the third sub-conductive layer comprises a metal conductive layer or a transparent conductive layer;
when the third sub-conductive layer is a transparent conductive layer, there is at least one third sub-conductive layer; and
when the third conductive layer is in the multi-layer structure, both the first anode connection line and the second anode connection line are located in at least one film of the third conductive layer;
wherein the first light emitting device emits light in one color of red and blue, the second light emitting device emits light in the other color of red and blue, and the third light emitting device emits green light.

20-21. (canceled)

22. A display apparatus, comprising: the display substrate of claim 1.
